(19) United States
(12) Patent Application Publication
(10) Pub. No.: US 2026/0032856 A1
(43) Pub. Date: Jan. 29, 2026

(54) COLD PLATE HEAT REMOVAL DEVICES WITH ENHANCED INTERNAL FLOW DISTRIBUTION AND EXTERNAL HOSE ROUTING

(71) Applicant: International Business Machines Corporation, Armonk, NY (US)

(72) Inventors: Shurong Tian, Mount Kisco, NY (US); Todd Edward Takken, Brewster, NY (US)

(21) Appl. No.: 18/782,325

(22) Filed: Jul. 24, 2024

(51) Int. Cl. H05K 7/20

(52) U.S. Cl. CPC H05K 7/20254; H05K 7/20272

(57) ABSTRACT

Heat removal devices and a method for manufacturing heat removal devices. The heat removal devices are configured to enhance external hose routing and enhance internal flow distribution.

### BACKGROUND

The present disclosure relates to heat removal from electronic devices, and, more specifically, enhanced arrangements of heat removal systems in electronic devices.

As power consumption of electronic devices increases with each new generation of such devices, heat removal through fluid-cooling is more frequently used to remove the heat generated from such devices. The fluids typically employed are air and water. At least some known heat removal systems for electronic devices use cold plates proximate the heat-generating portions of the electronic devices. The cold plates are coupled to a fluid supply conduit and a fluid return conduit. In general, compactness of the heat removal apparatus, low cost, and sufficient heat removal effectiveness are features to be considered for such fluid-cooling cold plates.

### SUMMARY

Heat transfer devices and a method are provided for enhance external hose routing and enhancing internal flow distribution.

In one aspect, a heat removal device for enhancing external hose routing is presented. The heat removal device includes a body. The body includes a first wall. The first wall defines a first fluid aperture and a second fluid aperture. The body also includes a second wall opposing the first wall. The first wall at least partially defines a first lateral axis and a second lateral axis perpendicular to the first lateral axis. The heat removal device also includes a first fluid riser in flow communication with the first fluid aperture. The first fluid riser is positionally fixed, and the first fluid riser is oriented to channel fluid into the body in a first direction at a first angle with respect to the first lateral axis. The heat removal device further includes a first fluid conduit in flow communication with the first fluid riser. The heat removal device also includes a second fluid riser in flow communication with the second fluid aperture. The second fluid riser is positionally fixed. The heat removal device further includes a second fluid conduit in flow communication with the second fluid riser.

In another aspect, a heat removal device for enhancing internal flow distribution is presented. The heat removal device includes a body. The body includes a first wall that defines a first lateral axis and a second lateral axis perpendicular to the first lateral axis. The first lateral axis and the second lateral axis intersect to define a geometric center of the body. The first wall also defines a first fluid aperture and a second fluid aperture disposed parallel to the second lateral axis and separated by the first lateral axis. The body also includes a second wall opposing the first wall. The body further includes a third wall orthogonal to the first wall and the second wall. The third wall is coupled to the first wall and the second wall. The first wall, the second wall, and the third wall define an outer periphery. The heat removal device also includes a thermally active region defined by the first wall, the second wall, and the third wall. The thermally active region defines an inner periphery. The inner periphery and the outer periphery are fluidly sealed. The heat removal device further includes a plurality of fins resident in the thermally active region extending from the second wall toward the first wall along an axis orthogonal to the first lateral axis and the second lateral axis. The plurality of fins define one or more heights, one or more orientations, and one or more pitches. The plurality of fins are thermally conductive. The plurality of fins are configured to channel a fluid from the first fluid aperture to the second aperture through a predetermined flow distribution defined by the one or more heights, the one or more orientations, and the one or more pitches.

In yet another aspect, a method of manufacturing a cold plate is presented. The method includes arranging a plurality of fluid risers and fluid conduits on a top wall of the cold plate such that access to mechanical mounting hardware, also positioned on the top wall of the cold plate, is not inhibited. The arranging includes forming a first fluid aperture and a second fluid aperture in the top wall of the cold plate. The arranging also includes coupling the top wall of the cold plate to a bottom wall of the cold plate in opposition to each other. A thermally active region is at least partially defined. The arranging further includes fixedly coupling a first fluid riser to the first fluid aperture and fixedly coupling a second fluid riser to the second fluid aperture. The arranging also includes coupling a first fluid conduit to the first fluid riser and coupling a second fluid conduit to the second fluid riser. The method also includes coupling the heat generating device to the bottom wall of the cold plate though the mechanical mounting hardware.

The present Summary is not intended to illustrate each aspect of every implementation of, and/or every embodiment of the present disclosure. These and other features and advantages will become apparent from the following detailed description of the present embodiment(s), taken in conjunction with the accompanying drawings.

### BRIEF DESCRIPTION OF THE DRAWINGS

The drawings included in the present application are incorporated into, and form part of, the specification. They illustrate embodiments of the present disclosure and, along with the description, serve to explain the principles of the disclosure. The drawings are illustrative of certain embodiments and do not limit the disclosure.

FIG. 1A is a block schematic diagram illustrating a device configured to remove heat from electronic devices from an overhead perspective, in accordance with some embodiments of the present disclosure.

FIG. 1B is a block schematic diagram illustrating the device shown in FIG. 1A from a side perspective, in accordance with some embodiments of the present disclosure.

FIG. 1C is a block schematic diagram illustrating the device shown in FIGS. 1A and 1B from an overhead perspective, in accordance with some embodiments of the present disclosure.

FIG. 2 is a block schematic diagram illustrating a device configured to remove heat from electronic devices from an overhead perspective, in accordance with some embodiments of the present disclosure.

FIG. 3 is a block schematic diagram illustrating a device configured to remove heat from electronic devices from an overhead perspective, in accordance with some embodiments of the present disclosure.

FIG. 4 is a block schematic diagram illustrating a device configured to remove heat from electronic devices from an overhead perspective, in accordance with some embodiments of the present disclosure.

FIG. 5A is a block schematic diagram illustrating a portion of a device configured to remove heat from electronic devices from an isometric perspective, in accordance with some embodiments of the present disclosure.

FIG. 5B is a block schematic diagram illustrating the portion of the device shown in FIG. 5A, in accordance with some embodiments of the present disclosure.

FIG. 6A is a block schematic diagram illustrating a portion of a device configured to remove heat from electronic devices from an isometric perspective, in accordance with some embodiments of the present disclosure.

FIG. 6B is a block schematic diagram illustrating the portion of the device shown in FIG. 6A, in accordance with some embodiments of the present disclosure.

FIG. 7A is a block schematic diagram illustrating a portion of a device configured to remove heat from electronic devices from an isometric perspective, in accordance with some embodiments of the present disclosure.

FIG. 7B is a block schematic diagram illustrating the portion of the device shown in FIG. 7A, in accordance with some embodiments of the present disclosure.

FIG. 8A is a block schematic diagram illustrating a portion of a device configured to remove heat from electronic devices from an isometric perspective, in accordance with some embodiments of the present disclosure.

FIG. 8B is a block schematic diagram illustrating the portion of the device shown in FIG. 8A, in accordance with some embodiments of the present disclosure.

FIG. 9A is a block schematic diagram illustrating a portion of a device configured to remove heat from electronic devices from an isometric perspective, in accordance with some embodiments of the present disclosure.

FIG. 9B is a block schematic diagram illustrating the portion of the device shown in FIG. 9A, in accordance with some embodiments of the present disclosure.

FIG. 10A is a block schematic diagram illustrating a portion of a device configured to remove heat from electronic devices from an isometric perspective, in accordance with some embodiments of the present disclosure.

FIG. 10B is a block schematic diagram illustrating the portion of the device shown in FIG. 10A, in accordance with some embodiments of the present disclosure.

FIG. 11A is a flowchart illustrating a process for manufacturing a cold plate, in accordance with some embodiments of the present disclosure.

FIG. 11B is a continuation of the flowchart shown in FIG. 11A, in accordance with some embodiments of the present disclosure.

While the present disclosure is amenable to various modifications and alternative forms, specifics thereof have been shown by way of example in the drawings and will be described in detail. It should be understood, however, that the intention is not to limit the present disclosure to the particular embodiments described. On the contrary, the intention is to cover all modifications, equivalents, and alternatives falling within the spirit and scope of the present disclosure.

### DETAILED DESCRIPTION

Aspects of the present disclosure relate to implementing a system configured for heat removal from electronic devices, and, more specifically, enhanced arrangements of heat removal systems in electronic devices. While the present disclosure is not necessarily limited to such applications, various aspects of the disclosure may be appreciated through a discussion of various examples using this context.

It will be readily understood that the components of the present embodiments, as generally described and illustrated in the Figures herein, may be arranged and designed in a wide variety of different configurations. Thus, the following detailed description of the embodiments of the apparatus, system, method, and computer readable storage medium of the present embodiments, as presented in the Figures, is not intended to limit the scope of the embodiments, as claimed, but is merely representative of selected embodiments.

Reference throughout this specification to “a select embodiment,” “at least one embodiment,” “one embodiment,” “another embodiment,” “other embodiments,” or “an embodiment” and similar language means that a particular feature, structure, or characteristic described in connection with the embodiment is included in at least one embodiment. Thus, appearances of the phrases “a select embodiment,” “at least one embodiment,” “in one embodiment,” “another embodiment,” “other embodiments,” or “an embodiment” in various places throughout this specification are not necessarily referring to the same embodiment.

The illustrated embodiments will be best understood by reference to the drawings, wherein like parts are designated by like numerals throughout. The following description is intended only by way of example, and simply illustrates certain selected embodiments of devices, systems, and processes that are consistent with the embodiments as claimed herein.

For purposes of this disclosure, “facilitating” an action includes performing the action, making the action easier, helping to carry the action out, or causing the action to be performed. Thus, by way of example and not limitation, instructions executing on one processor might facilitate an action conducted by semiconductor processing equipment, by sending appropriate data or commands to cause or aid the action to be performed. Where an actor facilitates an action by other than performing the action, the action is nevertheless performed by some entity or combination of entities.

As power consumption of electronic devices increases with each new generation of such devices, heat removal through fluid-cooling is more frequently used to remove the heat from such devices. The fluids typically employed are air and water. At least some known heat removal systems for electronic devices use cold plates proximate the heat-generating portions of the electronic devices. The cold plates are coupled to a fluid supply conduit and a fluid return conduit. In general, compactness of the heat removal apparatus, low cost, and sufficient heat removal effectiveness are features to be considered for such fluid-cooling cold plates.

In general, the cold plates and the respective electronic devices are configured to reside in a server chassis. Many server chassis are configured according to industry standards. One such standard is for the height of the chassis, often referred to in terms of “rack units,” where one rack unit is abbreviated as 1RU, or, in some instances, 1U. 1U is 44.45 millimeters (mm). Many known cold plates and their respective devices are configured to reside in a chassis with a height of 1U. One important feature of a cold plate is that the cold plate should not increase the system height. Therefore, for 1U tall sever chassis, the cold plate should be low profile.

Some known cold plates and the associated electronic device are sized with respect to height to take up in excess of approximately 36 mm to approximately 42 mm. For those electronic devices that are approximately 3 mm to approximately 5 mm in height, the respective cold plates are at most 31 mm to 39 mm in height in order to fit within the 1U chassis height.

In some known cold plates, hardware for channeling cooling fluid to and from the cold plates is positioned on top of the cold plate. Such cooling fluid hardware includes fixtures such as ports, piping or hoses, and pumping devices that extend from a lid positioned on the top of the cold plate. Some of such fixtures extend upward a significant distance, thereby expending space that could be otherwise used. For example, some of the known cold plates (not including the cooling fluid hardware) are approximately 27 mm in height, i.e., within a range of approximately 24 mm to approximately 27.5 mm, excluding the electronic device. Therefore, an electronic device of approximately 3 mm to approximately 5 mm will extend the height of such combined apparatus to at least 30 mm. Such configurations further include a manifold to redirect flow, which adds approximately 5 mm to approximately 15 mm to the overall height. Moreover, for some known cold plates, cooling fluid hardware also includes swivel devices that further extend the respective fluid fixtures upward. Furthermore, the greater size and complication of the fluid fixtures tends to increase the cost as well as the size of the respective cold plates. Therefore, for such configurations, one cold plate and respective electronic device may not fit in the standard 1U server chassis.

In addition, some known cold plates use fins for heat transfer from the heat generating devices they are coupled to into the fluid in contact with the fins. However, many of the known heat plates do not have customized flow patterns for the intended use.

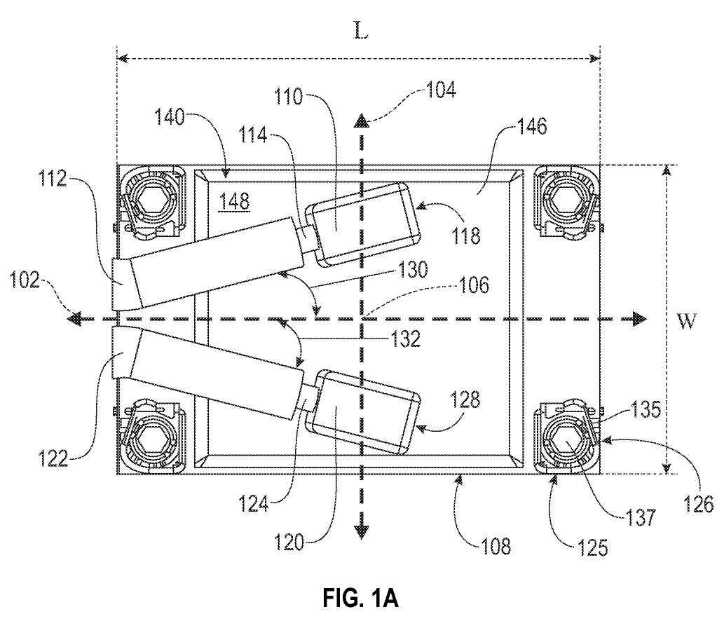

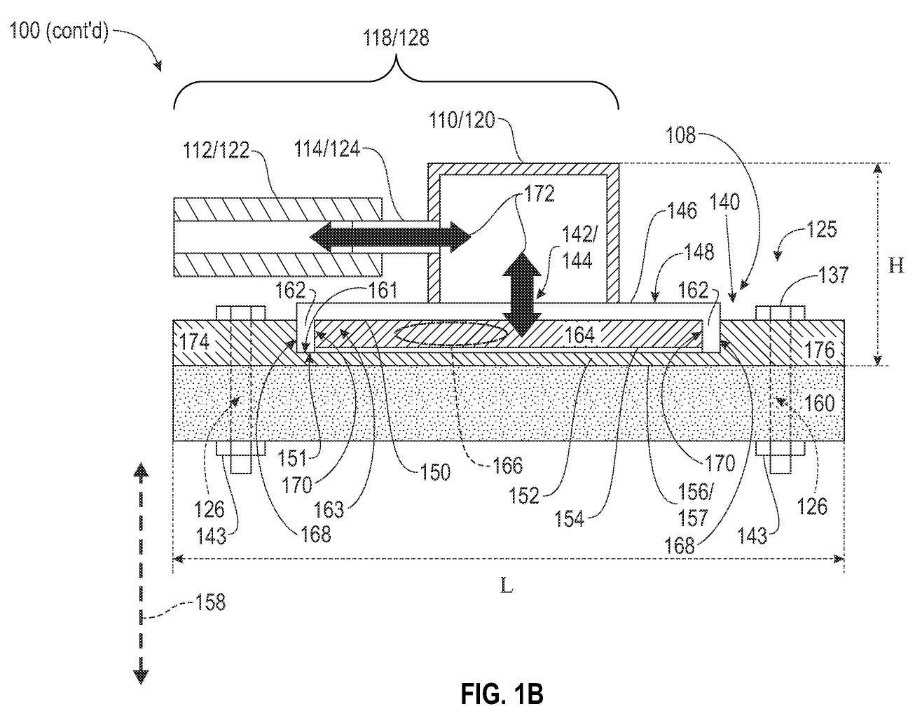

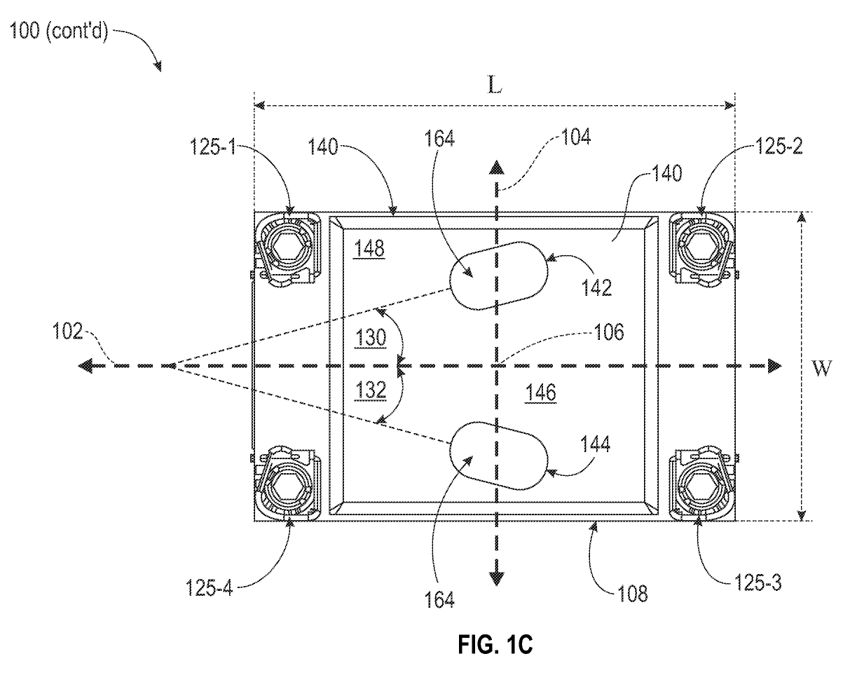

Referring to FIG. 1A, a block schematic diagram is presented illustrating a device 100 configured to remove heat from electronic devices from an overhead perspective, in accordance with some embodiments of the present disclosure. In some embodiments, the device 100 is a cold plate heat removal device. In some embodiments, the device 100 is a heat removal device configured with enhanced external fluid conduit routing to avoid mechanical obstructions. In some embodiments, the device 100 is a heat removal device configured for enhanced flow distribution internally to improve heat removal. In some embodiments, the device 100 is configured to enhance both external fluid conduit routing and enhanced internal flow distribution.

In some embodiments, the device 100 defines a first lateral axis 102 and a second lateral axis 104. The first lateral axis 102 and the second lateral axis 104 are perpendicular to each other and define a geometric center 106 of the device 100.

In one or more embodiments, the device 100 includes a body 108. The body 108 is fabricated from any materials that enable operation of the device 100 as described herein. The body defines a first distance, i.e., a length L parallel to the first lateral axis 102 and a second distance, i.e., a width W parallel to the second lateral axis 104. In some embodiments, the width W is within a range of approximately 60 millimeters (mm) to approximately 120 mm (not shown to scale). Is some embodiments, the length L is within a range of approximately 72 mm to approximately 180 mm (not shown to scale). The length L and the width W are discussed further herein.

The device 100 also includes a first fluid riser 110 fixedly coupled to the body 108. As such, the first fluid riser 110 is fixed and configured to not swivel. The device 100 further includes a first fluid conduit 112 coupled in flow communication with the first fluid riser 110 through a first conduit connector 114. The first fluid riser 110, the first fluid conduit 112, and the first conduit connector 114 are fabricated from any materials that enable operation of the device 100 as described herein. In some embodiments, the first fluid conduit 112 is a rubber hose. In some embodiments, the first fluid conduit 112 is metallic piping. In at least some embodiments, the first fluid conduit 112, the first conduit connector 114, and the first fluid riser 110 define a cooling fluid inlet channel 118.

In at least some embodiments, the device 100 includes a second fluid riser 120 fixedly coupled to the body 108. As such, the second fluid riser 120 is fixed and configured to not swivel. The device 100 further includes a second fluid conduit 122 coupled in flow communication with the second fluid riser 120 through a second conduit connector 124. The second fluid riser 120, the second fluid conduit 122, and the second conduit connector 124 are fabricated from any materials that enable operation of the device 100 as described herein. In some embodiments, the second fluid conduit 122 is a rubber hose. In some embodiments, the second fluid conduit 122 is metallic piping. In at least some embodiments, the second fluid conduit 122, the second conduit connector 124, and the second fluid riser 120 define a cooling fluid outlet channel 128.

In one or more embodiments, the body 108 includes a first wall, i.e., a top wall 140. In some embodiments, the top wall 140 is referred to as the lid of the device 100. The top wall 140 includes a lid surface 146 that at least partially defines the length L and the width W that in turn define a plane 148. As such, the first lateral axis 102 and the second lateral axis 104 at least partially define the plane 148.

In some embodiments, the device 100 includes mechanical mounting hardware 125 positioned proximate to each of the four corners of the top wall 140 (only one labeled). The number of four sets of mechanical mounting hardware 125 is non-limiting. Each set of the mechanical mounting hardware 125 includes a loading structure 135 that defines a fastener aperture 126 configured to receive a fastener 137. In some embodiments, the fastener 137 is a hex bolt. In some embodiments, the fastener 137 is any fastening mechanism that enables operation of the device 100 as described herein. The mechanical mounting hardware 125 is configured to couple the device 100 to a heat generating device (see FIG. 1B), such as, and without limitation, electronic devices such as, and without limitation, a computer processor chip.

In one or more embodiments, the first fluid riser 110 and the second fluid riser 120 are positioned in opposition with respect to the first lateral axis 102 and coincident with the second lateral axis 104, thereby orienting the first fluid riser 110 and the second fluid riser 120 symmetrically with respect to the first lateral axis 102. Moreover, in some embodiments, the cooling fluid inlet channel 118 is oriented with respect to the first lateral axis 102 with a first angle 130. Similarly, in some embodiments, the cooling fluid outlet channel 128 is oriented with respect to the first lateral axis 102 with a second angle 132. In some embodiments the absolute values of the first angle 130 and the second angle 132 are the same. In some embodiments, the absolute values of the first angle 130 and the second angle 132 are different. In some embodiments, the first angle 130 determines the orientation and direction of the cooling fluid inlet channel 118 and the second angle 132 determines the orientation and direction of the cooling fluid outlet channel 128.

The configuration, including the positioning and orientation, of the first fluid riser 110 and the second fluid riser 120 facilitate access to the heat generating device positioned under the body 108. Specifically, the orientations of the cooling fluid inlet channel 118 and the cooling fluid outlet channel 128 through the respective first angle 130 and second angle 132 facilitate mitigating interference with access to the mechanical mounting hardware 125 for disassembling the device 100 from the heat generating device (see FIG. 1B). Such ease of access to the fasteners 137 also facilitates removal of the device 100 for inspection, maintenance, and replacement. In addition, the positioning and orientations as discussed above facilitate integration of the heat generating device into a respective computing system through permitting the use of fluid conduits with larger radii and larger bend radii (discussed further herein). As such, the increased design flexibility with respect to the size of the fluid conduits and the respective bend radii facilitates integrating larger heat generating devices, such as larger and more powerful processors, into computer systems.

FIG. 1B is a block schematic diagram illustrating the device 100 shown in FIG. 1A from a side perspective, in accordance with some embodiments of the present disclosure. Continuing to refer to FIG. 1A as well, in one or more embodiments, the body 108 includes the first wall, i.e., a top wall 140. The top wall 140 defines a first fluid aperture 142 and a second fluid aperture 144 (both discussed further with respect to FIG. 1C). The first fluid aperture 142 and the second fluid aperture 144 are coupled in flow communication with the respective first fluid riser 110 and second fluid riser 120, respectively. The top wall 140 also includes an active area upper surface 150 opposite the lid surface 146.

In one or more embodiments, the body 108 also includes a second wall, i.e., a bottom wall 152 opposing the top wall 140. The bottom wall 152 includes an active area bottom surface 154. The bottom wall 152 also includes a body-to-heat generating device interface 156 opposite to the active area bottom surface 154. The bottom wall 152 is integrally coupled to a first flange 174 and a second flange 176. The first flange 174 and the second flange 176 at least partially define the fastener apertures 126.

A heat generating device 160 is coupled to the device 100 at the body-to-heat generating device interface 156 by the fasteners 137 and the respective nuts 143. In some embodiments, the heat generating device 160 is a packaged chip with a height in the range of approximately 3 mm to approximately 5 mm. In some embodiments, a thermal interface material 157 is positioned at the body-to-heat generating device interface 156, where any material that enables operation of the device 100 as described herein is used.

In some embodiments, the first fluid riser 110, the second fluid riser 120, and the second wall’s body-to-heat generating device interface 156 define a third distance, i.e., a height H of the device 100 parallel to a third axis 158 orthogonal to the first plane 148, where the height H less than the length L and the width W. In some embodiments, the height H has a value between approximately 15 mm and approximately 20 mm (not shown to scale). In some embodiments, the height H is a maximum of approximately 25 mm. Therefore, the device 100 with the cooling fluid hardware of the cooling fluid inlet channel 118 and the cooling fluid outlet channel 128, as well as including the heat generating device 160, has a relatively low profile in comparison to many known cold plates. Accordingly, more than one of the devices 100 with the cooling fluid hardware, as well as the respective heat generating devices 160, will fit into a 1U server chassis.

In at least some embodiments, the body 108 further includes a third wall, i.e., a side wall 162 that is orthogonal to, and coupled to, the top wall 140 and the bottom wall 152. In some embodiments, the top wall 140 and the side wall 162 are unitarily fabricated to form a single top wall 140 unit. The top wall 140, the bottom wall 152, and the side wall 162 define a cavity 163 that encloses a thermally active region 164 that includes a plurality of fins 166 (only a portion of the fins are shown within the respective dashed ellipse). The plurality of fins 166 resident in the thermally active region 164 extend from the bottom wall 152 toward the top wall 140 along the third axis 158. In some embodiments, the plurality of fins 166 are in thermal contact with the top wall 140 and the bottom wall 152. The plurality of fins 166 are thermally conductive and are configured to channel a fluid from the first fluid aperture 142 to the second fluid aperture 144 through a predetermined flow distribution. The fins 166 are discussed further herein.

In some embodiments, the bottom wall 152 defines a bottom wall periphery 151 and the side wall 162 defines a side wall periphery 161. The bottom wall 152 and the side wall 162 are coupled to each other at their respective peripheries 151 and 161. In addition, the bottom wall 152 and the side wall 162 define an outer periphery 168. In addition, in such embodiments, the bottom wall 152 and the side wall 162, including the thermally active region 164 define an inner periphery 170 that is concentric with the outer periphery 168 with respect to the side wall 162. The inner periphery 170 and the outer periphery 168 are fluidly sealed, thereby fluidly sealing the cavity 163 including the thermally active region 164.

In one or more embodiments, a flow pattern through the device 100 is indicated by the arrows 172. The flow pattern includes chilled water channeled from a chilled water system (not shown) through the first fluid conduit 112, the first conduit connector 114, first fluid riser 110, and the first fluid aperture 142 into the thermally active region 164. The flow pattern further includes warmed water channeled from the thermally active region 164 through the second fluid aperture 144, the second fluid riser 120, the second conduit connector 124, and the second fluid conduit 122 back to the chilled water system. The fluid flow patterns through various embodiments of the thermally active region 164 are discussed further herein. For purposes of this disclosure, the term “flow pattern” defines the transport and distribution of the fluid through the various portions of the device 100, including the thermally active region 164, where the pattern includes without limitation, a distribution of flow velocities, distributed flow masses, volumetric flow rates, and flow directions.

Referring to FIG. 1C, a block schematic diagram is presented illustrating the device 100 shown in FIGS. 1A and 1B from an overhead perspective, in accordance with some embodiments of the present disclosure. The mechanical mounting hardware 125 are labeled as 125-1, 125-2, 125-3, and 125-4 as shown in FIG. 1C, where the number of four is non-limiting. Also continuing to refer to FIGS. 1A and 1B, and in contrast, FIG. 1C shows the components of the cooling fluid inlet channel 118 including the first fluid conduit 112, the first conduit connector 114, and the first fluid riser 110 are removed to show the first fluid aperture 142 and the thermally active region 164 beneath. Similarly, the thermally active region 164 through the second fluid aperture 144 are shown with the components of the cooling fluid outlet channel 128 including the second fluid riser 120, the second conduit connector 124, and the second fluid conduit 122 removed.

The configuration of the device 100, including the positioning of the cooling fluid inlet channel 118 and the cooling fluid outlet channel 128 on the lid surface 146 of the top wall 140, in conjunction with the orientations as indicated by the first angle 130 and the second angle 132 facilitate ease of access to the heat generating device 160. Specifically, the cooling fluid inlet channel 118 and the cooling fluid outlet channel 128 are directed away from the mechanical mounting hardware 125 to facilitate ease of access to the fasteners 137 coupling the device 100 to the heat generating device 160. For example, rather than disconnecting the cooling fluid inlet channel 118 and the cooling fluid outlet channel 128, the fasteners 137 resident in the fastener apertures 126 are easily accessed and removed to permit lifting the device 100 off of the heat generating device 160.

In some embodiments, for maintenance activities such as inspecting the heat generating device 160, full removal of the device 100 may not be warranted. Under some circumstances, partial disassembly will be sufficient. In some embodiments, such partial disassembly operations include removal of the fasteners 137 from the mechanical mounting hardware 125-2 and 125-3 and to merely loosen the fasteners 137 in the mechanical mounting hardware 125-1 and 125-4. Sufficient play in the top wall 140 and the bottom wall 152 to lift the device 100 facilitates executing the desired activities with at least a partial view of the heat generating device 160. In such circumstances, the configuration of the device 100, including the positioning and orientation of the first fluid conduit 112 and the second fluid conduit 122 facilitate repeated partial disassembly operations. In addition, particular material selections for the first fluid conduit 112 and the second fluid conduit 122 with the desired flexibility features further enhances partial disassembly. In some embodiments, the decreased need to remove the device 100 from the heat generating device 160 extends the lifespan of the device 100.

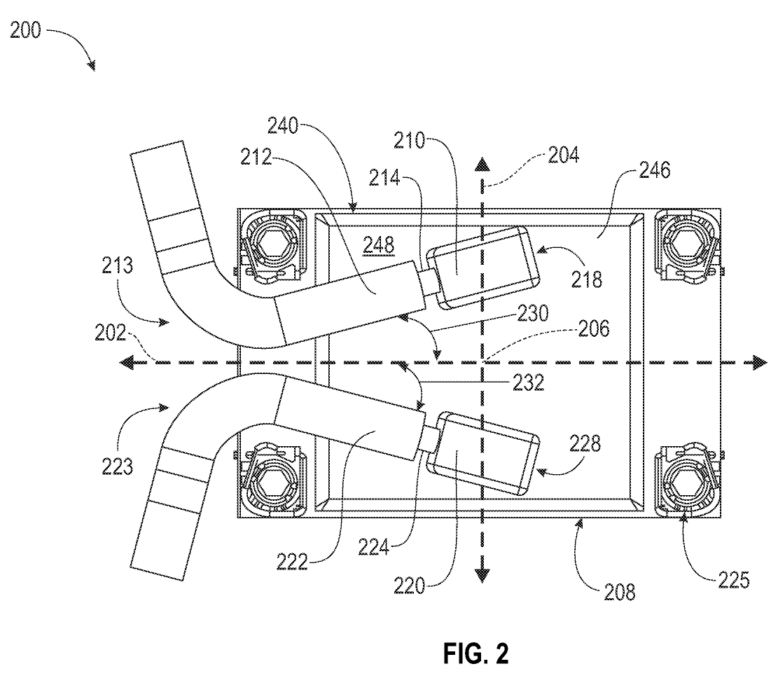

Referring to FIG. 2, a block schematic diagram is presented illustrating a device 200 configured to remove heat from electronic devices from an overhead perspective, in accordance with some embodiments of the present disclosure. Those components of the device 200 that are similar to the device 100 shown in FIGS. 1A-1C have similar numbering in FIG. 2. The first fluid conduit 212 includes a bend 213 that directs the flow of fluid to the device 200 from a direction parallel to the second lateral axis 204. Similarly, the second fluid conduit 222 includes a bend 223 that directs the flow of fluid from the device 200 in a direction parallel to the second lateral axis 204. However, in some embodiments, the angular values associated with the bends 213 and 223 are any values that enable operation of the embodiments described herein. Such operations include, without limitation, the partial disassembly operations previously described. Accordingly, the configuration of the device 200 and the design flexibility with respect to the routings of the cooling fluid inlet channel 218 and the cooling fluid outlet channel 228 facilitates increasing the available room within the respective servers for additional components through facilitating more efficient and effective routing of the cooling conduits therein.

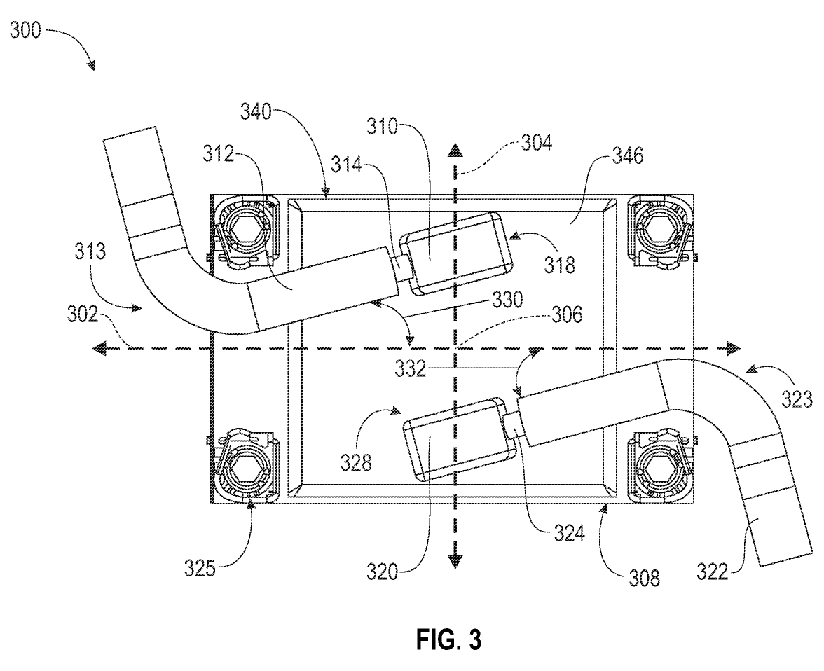

Referring to FIG. 3, a block schematic diagram is presented illustrating a device 300 configured to remove heat from electronic devices from an overhead perspective, in accordance with some embodiments of the present disclosure. Those components of the device 300 that are similar to the device 100 shown in FIGS. 1A-1C and device 200 shown in FIG. 2 have similar numbering in FIG. 3. In some embodiments, it will not be practical to position the first fluid conduit 312 with the bend 313 and the second fluid conduit 322 with the bend 323 on the same side of the device 300. One such reason includes additional devices on the lid surface 346. Therefore, in some embodiments, the first fluid conduit 312 directs the flow of fluid to the device 300 from a direction parallel to the second lateral axis 304. In contrast, the second fluid conduit 322 directs the flow of fluid from the device 300 in a direction also parallel to the second lateral axis 304; however, the flow is in a direction opposite to that of the first fluid conduit 312. As such, the first fluid conduit 312 and the second fluid conduit 322 are positioned on opposing sides of the device 300.

In some embodiments, the angular values associated with the bends 313 and 323 are any values that enable operation of the embodiments described herein. In some embodiments, the angular values for the angles 330 and 332 are substantially similar, In some embodiments, the angular values for the angles 330 and 332 are any values that enable operation of the device 300 as described herein. In some embodiments, the first fluid conduit 312 and the second fluid conduit 322 do not cross the first lateral axis 302. In some embodiments, the angular values of the first bend 313, the second bend 323, the first angle 330, and the second angle 332 facilitate the first fluid conduit 312 and the second fluid conduit 322 crossing the first lateral axis 302. The orientations and positions of the cooling fluid inlet channel 318 and the cooling fluid outlet channel 328 facilitate the use of the tooling used to remove the fasteners 337 from the fastener apertures 326. In addition, the configuration of the device 300, including the orientations and positions of the cooling fluid inlet channel 318 and the cooling fluid outlet channel 328 facilitate operations including, without limitation, the partial disassembly operations previously described. In addition, such partial disassembly may include any two adjacent fasteners 337 of the mechanical mounting hardware 325 being removed and the other two fasteners 337 of the mechanical mounting hardware 325 loosened to at least partially lift the top wall 340 and the bottom wall 352 of the device 300 from one side of the device 300. Moreover, the design flexibility with respect to the routings of the cooling fluid inlet channel 318 and the cooling fluid outlet channel 328 facilitates the inclusion of additional devices on the lid surface 346 and increasing the available room within the respective servers for additional components through facilitating more efficient and effective routing of the cooling conduits therein.

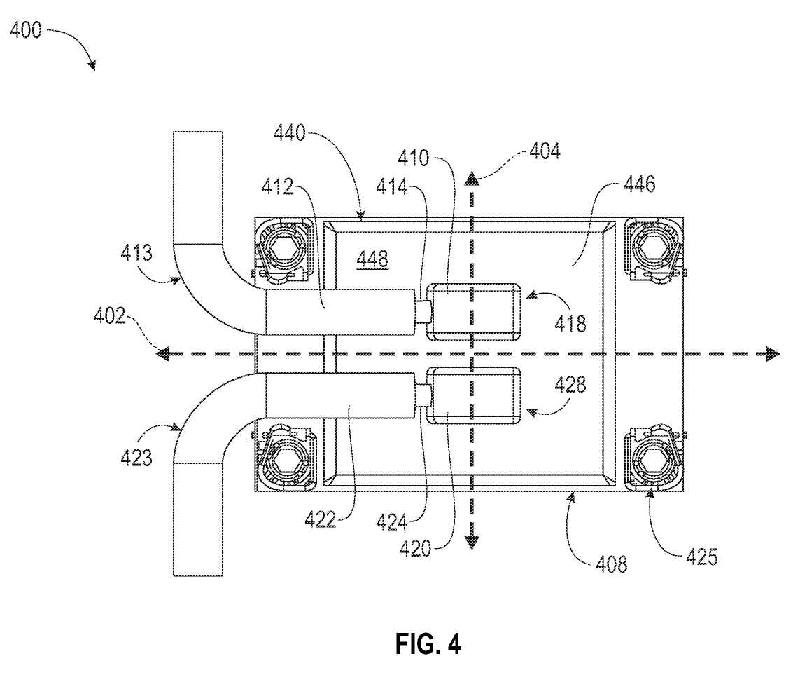

Referring to FIG. 4, a block schematic diagram is presented illustrating a device 400 configured to remove heat from electronic devices from an overhead perspective, in accordance with some embodiments of the present disclosure. Those components of the device 400 that are similar to the device 100 shown in FIGS. 1A-1C, the device 200 shown in FIG. 2, and the device 300 shown in FIG. 3 have similar numbering in FIG. 4. The device 400 is similar to the device 200 with respect to the cooling fluid inlet channel 418 and the cooling fluid outlet channel 428 that are oriented to channel fluid to and from the device 400 at a direction parallel to the second lateral axis 404. In addition, the respective bends 413 and 423 define angles of approximately 90 degrees such that the portions of the cooling fluid inlet channel 418 after the bend 413 and the cooling fluid outlet channel 428 prior to the bend 423 are parallel to first lateral axis 402. The first fluid aperture (not shown in FIG. 4) is defined in the lid surface 446, where the major axis of the first fluid aperture is parallel to the first lateral axis 402 and the minor axis is coincident with the second lateral axis 404. The second fluid aperture (not shown in FIG. 4) is defined in the lid surface 446, where the major axis of the second fluid aperture is parallel to the first lateral axis 402 and the minor axis is coincident with the second lateral axis 404. The configuration of the device 400 facilitates operations including, without limitation, the partial disassembly operations previously described. Accordingly, the configuration of the device 400 provides design flexibility with respect to the routings of the cooling fluid inlet channel 418 and the cooling fluid outlet channel 428. In addition, the configuration of the device 400 facilitates increasing the available room within the respective servers for additional components through facilitating more efficient and effective routing of the cooling conduits therein.

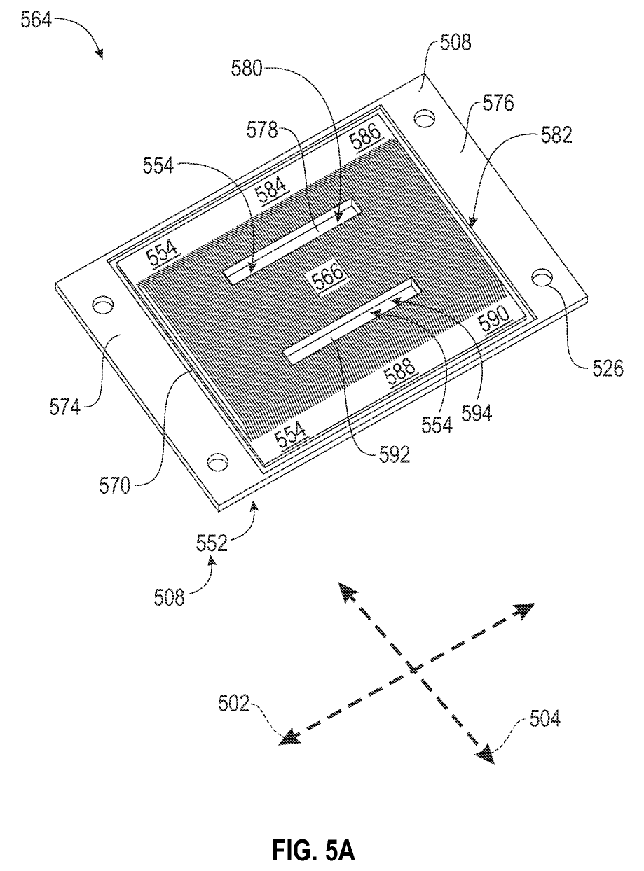

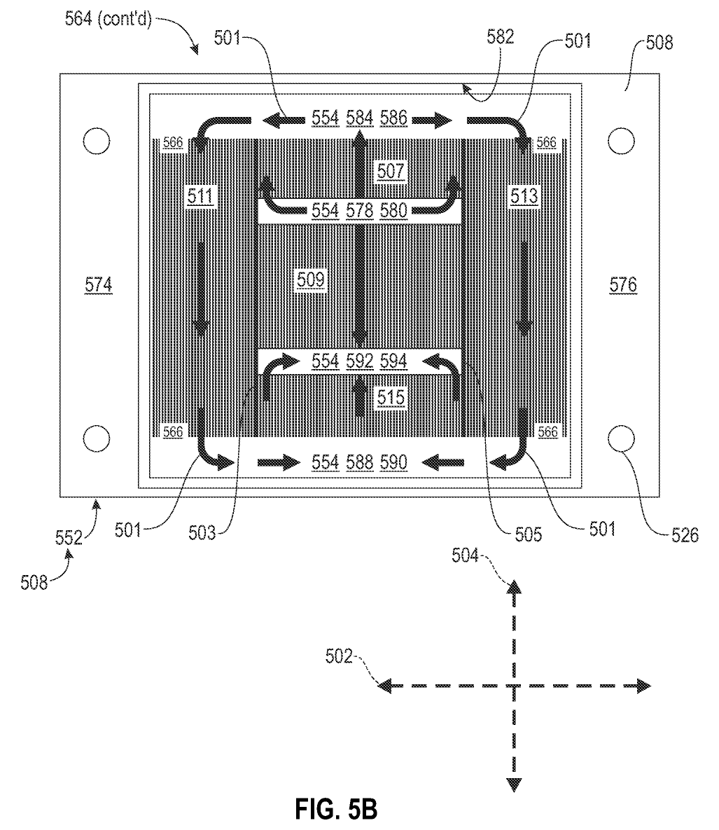

Referring to FIG. 5A, a block schematic diagram is presented illustrating a portion of a device configured to remove heat from electronic devices from an isometric perspective, in accordance with some embodiments of the present disclosure. In at least some embodiments, the portion of the device is the thermally active region 564 (described as the thermally active region 164 with respect to FIGS. 1B and 1C). Accordingly, FIG. 5A illustrates a portion of the device 100 (see FIG. 1B) with the first fluid riser 110, the second fluid riser 120. the top wall 140 (including the lid surface 146), and the side wall 162 removed to show the thermally active region 564. In addition to the device 100, in some embodiments, the thermally active region 564 is configured for use with any one of the devices 200, 300, and 400 as shown in FIGS. 2-4, respectively. Those components of the thermally active region 564 that are similar to those components of the device 100 shown in FIGS. 1A-1C, the device 200 shown in FIG. 2, the device 300 shown in FIG. 3, and the device 400 shown in FIG. 4 have similar numbering in FIG. 5A. The first lateral axis 502 and the second lateral axis 504 are shown for reference.

In one or more embodiments, the thermally active region 564 includes a portion of the body 508 including the bottom wall 552 that includes the active area bottom surface 554. The bottom wall 552 also includes a body-to-heat generating device interface 156 (see FIG. 1B) opposite to the active area bottom surface 554. In some embodiments, the heat generating device 160 (see FIG. 1B) is coupled to the body 508 at the body-to-heat generating device interface 156. Accordingly, the thermally active region 564 is configured to remove the heat generated by the heat generating device 160.

In at least some embodiments, the bottom wall 552 is integrally coupled to the first flange 574 and the second flange 576. The first flange 574 and the second flange 576 define the fastener apertures 526 (only one labeled in FIG. 5A). In some embodiments, the thermally active region 564 includes the plurality of fins 566 that are integrally formed with the bottom wall 552. In some embodiments, the plurality of fins 566 extend from the active area upper surface 150 of the top wall 140 (see FIG. 1B) to the bottom wall 552 along the third axis 158 (see FIG. 1B). As such, in some embodiments, the plurality of fins 566 are in thermal contact with the active area upper surface 150 of the top wall 140 and the bottom wall 552. The plurality of fins 566 are thermally conductive and are configured to channel a fluid from the first fluid aperture 142 (see FIG. 1C) to the second fluid aperture 144 (see FIG. 1C) through a predetermined flow distribution. Such configuration of the fins 566 includes a predetermined height, a predetermined pitch, and a predetermined orientation. In some embodiments, the fins 566 have a height in the range between approximately 2 mm to approximately 5 mm. In some embodiments, the fins 566 have any height value that enables operation of the thermally active region 564 as described herein. The predetermined pitches and orientations are discussed further herein.

In one or more embodiments, the cooling fluid inlet channel 118 (see FIG. 1A) is coupled in flow communication with the first fluid aperture 142. The thermally active region 564 includes an inlet plenum 578 that is coupled in flow communication with the first fluid aperture 142. In some embodiments, the inlet plenum 578 is rectangular and is oriented with the long dimension extending parallel to the first lateral axis 502 and the short dimension extending parallel to the second lateral axis 504. In some embodiments, the inlet plenum 578 has any shape and configuration that enables operation of the thermally active region 564 as described herein. The inlet plenum 578 is a fluid entrance flow distribution region that defines a first flow area 580. As used herein, the term “flow area” is used to describe a surface area of the active area bottom surface 554 defined for the respective flow distribution region.

In some embodiments, the inlet plenum 578 is fabricated through removing a predetermined portion of the fins 566 through any mechanism that enables operation of the thermally active region 564 as described herein, including, without limitation, mechanical grinding and chemical etching. In some embodiments, the fins 566 in the predetermined region are reduced to a predetermined height less than the full height of the fins 566. In some embodiments, the fins 566 in the predetermined region are completely removed. In some embodiments, the inlet plenum 578 is formed by coupling the fins 566 to the active area bottom surface 554 of the bottom wall 552 in a predetermined pattern that defines the inlet plenum 578. As such, the first flow area 580 defines a portion of the active area bottom surface 554 exposed to the incoming fluid. The dimensions of the inlet plenum 578 include the flow area 580 and the height of the fins 566 (not shown). The inlet plenum 578 is configured to receive the incoming heat removal fluid (not shown in FIG. 5A) and initiate the respective flow distribution within the thermally active region 564 as described further with respect to FIG. 5B. Accordingly, the inlet plenum 578 is configured to provide the flow distribution characteristics to the incoming fluid that facilitate the overall flow distribution through the thermally active region 564.

In some embodiments, a peripheral channel 582 is defined in the bottom wall 552 proximate the two edges of the body 508 that are defined parallel to the first lateral axis 502. The peripheral channel 582 is further defined proximate the first flange 574 and the second flange 576 and oriented parallel to the second lateral axis 504. The peripheral channel 582 is configured to receive the side wall 162 (see FIG. 1B) to fluidly seal the thermally active region 564. Therefore, the peripheral channel 582 is continuous about the inner periphery 570 of the thermally active region 564.

In at least some embodiments, the thermally active region 564 includes a first fluid channel 584 that is coupled in flow communication with the inlet plenum 578 via a portion of the fins 566 (described further with respect to FIG. 5B). In some embodiments, the first fluid channel 584 is a rectangular heat transfer flow distribution region that is oriented with the long dimension extending parallel to the first lateral axis 502 and the short dimension extending parallel to the second lateral axis 504. In some embodiments, the first fluid channel 584 has any shape and configuration that enables operation of the thermally active region 564 as described herein. The first fluid channel 584 is a lateral peripheral flow region that defines a second flow area 586 extending along a portion of the peripheral channel 582. Accordingly, a respective portion of the peripheral channel 582 with the side wall 162 inserted therein, the bottom wall 552, the fins 566, and the top wall 140 (see FIG. 1B) define the fluid flow structural boundaries of the first fluid channel 584.

In some embodiments, the first fluid channel 584 is fabricated through removing a predetermined portion of the fins 566 through any mechanism that enables operation of the thermally active region 564 as described herein, including, without limitation, mechanical grinding and chemical etching. In some embodiments, the fins 566 in the predetermined region are reduced to a predetermined height less than the full height of the fins 566. In some embodiments, the fins 566 in the predetermined region are completely removed. In some embodiments, the first fluid channel 584 is formed by coupling the fins 566 to the active area bottom surface 554 of the bottom wall 552 in a predetermined pattern that defines the first fluid channel 584. As such, the second flow area 586 defines a portion of the active area bottom surface 554 exposed to the fluid. The dimensions of the first fluid channel 584 include the second flow area 586 and the height of the fins 566 (not shown). The first fluid channel 584 is configured to receive the incoming heat removal fluid (not shown in FIG. 5A) and channel the fluid to the fins 566 that define the respective flow distribution within the thermally active region 564 as described further with respect to FIG. 5B. Accordingly, the first fluid channel 584 is configured to provide the flow distribution characteristics to the fluid that facilitate the overall flow distribution through the thermally active region 564.

In at least some embodiments, the thermally active region 564 includes a second fluid channel 588 that is coupled in flow communication with a portion of the fins 566 (described further with respect to FIG. 5B). In some embodiments, the second fluid channel 588 is a rectangular heat transfer flow distribution region that is oriented with the long dimension extending parallel to the first lateral axis 502 and the short dimension extending parallel to the second lateral axis 504. In some embodiments, the second fluid channel 588 has any shape and configuration that enables operation of the thermally active region 564 as described herein. The second fluid channel 588 is a lateral peripheral flow region that defines a third flow area 590 extending along a portion of the peripheral channel 582. Accordingly, a respective portion of the peripheral channel 582 with the side wall 162 inserted therein, the bottom wall 552, the fins 566, and the top wall 140 (see FIG. 1B) define the fluid flow structural boundaries of the second fluid channel 588.

In some embodiments, the second fluid channel 588 is fabricated through removing a predetermined portion of the fins 566 through any mechanism that enables operation of the thermally active region 564 as described herein, including, without limitation, mechanical grinding and chemical etching. In some embodiments, the fins 566 in the predetermined region are reduced to a predetermined height less than the full height of the fins 566. In some embodiments, the fins 566 in the predetermined region are completely removed. In some embodiments, the second fluid channel 588 is formed by coupling the fins 566 to the active area bottom surface 554 of the bottom wall 552 in a predetermined pattern that defines the second fluid channel 588. As such, the third flow area 590 defines a portion of the active area bottom surface 554 exposed to the fluid. The dimensions of the second fluid channel 588 include the third flow area 590 and the height of the fins 566 (not shown). The second fluid channel 588 is configured to receive the incoming heat removal fluid (not shown in FIG. 5A) from a portion of the fins 566 and channel the respective flow distribution within a finned portion of the thermally active region 564 as described further with respect to FIG. 5B. In the embodiment illustrated in FIG. 5A, the second fluid channel 588 is substantially similar to the first fluid channel 584, including the third flow area 590 and respective rectangular dimensions being substantially similar to the second flow area 586 and respective rectangular dimensions. Accordingly, the second fluid channel 588 is configured to provide the flow distribution characteristics to the fluid that facilitate the overall flow distribution through the thermally active region 564.

In one or more embodiments, the thermally active region 564 includes an outlet plenum 592 that is coupled in flow communication with the second fluid aperture 144. In some embodiments, the outlet plenum 592 is rectangular and is oriented with the long dimension extending parallel to the first lateral axis 502 and the short dimension extending parallel to the second lateral axis 504. In some embodiments, the outlet plenum 592 has any shape and configuration that enables operation of the thermally active region 564 as described herein. The outlet plenum 592 is a fluid exit flow distribution region that defines a fourth flow area 594.

In some embodiments, the outlet plenum 592 is fabricated through removing a predetermined portion of the fins 566 through any mechanism that enables operation of the thermally active region 564 as described herein, including, without limitation, mechanical grinding and chemical etching. In some embodiments, the fins 566 in the predetermined region are reduced to a predetermined height less than the full height of the fins 566. In some embodiments, the fins 566 in the predetermined region are completely removed. In some embodiments, the outlet plenum 592 is formed by coupling the fins 566 to the active area bottom surface 554 of the bottom wall 552 in a predetermined pattern that defines the outlet plenum 592. As such, the fourth flow area 594 defines a portion of the active area bottom surface 554 exposed to the exiting fluid. The dimensions of the outlet plenum 592 include the flow area 594 and the height of the fins 566 (not shown). The outlet plenum 592 is configured to receive the heat removal fluid from the second fluid channel 588 (not shown in FIG. 5A) via a portion of the fins 566 and channel the respective flow distribution from the thermally active region 564 as described further with respect to FIG. 5B. The fluid exiting the thermally active region 564 is channeled through the outlet plenum 592 into the cooling fluid outlet channel 128 (see FIG. 1A) via the second fluid aperture 144. In the embodiment illustrated in FIG. 5A, the outlet plenum 592 is substantially similar to the inlet plenum 578, including the fourth flow area 594 and respective rectangular dimensions being substantially similar to the first flow area 580 and respective rectangular dimensions. Accordingly, the outlet plenum 592 is configured to provide the flow distribution characteristics to the exiting fluid that facilitate the overall flow distribution through the thermally active region 564.

In some embodiments, the plurality of fins 566 with flow channels therebetween are segments into five separate regions. These five regions include a first fin flow region 507, a second fin flow region 509, a third flow regions 511, a fourth flow region 513 and a fifth flow region 515. These five fin flow regions 507-515 are discussed further with respect to FIG. 5B. Unless otherwise indicated, the fins 566 and their flow channels have the same pitch (i.e., fin separation) within each of the five fin flow regions 507-515. In some embodiments, the pitch of the fins is represented numerically in units of a number of fins per unit length.

Accordingly, the inlet plenum 578, the first fluid channel 584, the second fluid channel 588, and the outlet plenum 592 are serially coupled in flow communication. The details of fluid flow through the thermally active region 564 are presented with respect to FIG. 5B.

Referring to FIG. 5B, a block schematic diagram is presented illustrating the portion of the device shown in FIG. 5A, in accordance with some embodiments of the present disclosure. In at least some embodiments, the portion of the device is the thermally active region 564. Accordingly, FIG. 5B illustrates fluid flow through a portion of the device 100 (see FIG. 1B) with the first fluid riser 110, the second fluid riser 120. the top wall 140 (including the lid surface 146 and the active area upper surface 150), and the side wall 162 removed to show the thermally active region 564. In addition to the device 100, in some embodiments, the thermally active region 564 is configured for use with any one of the devices 200, 300, and 400 as shown in FIGS. 2-4, respectively. Those components of the thermally active region 564 that are similar to those components of the device 100 shown in FIGS. 1A-1C, the device 200 shown in FIG. 2, the device 300 shown in FIG. 3, and the device 400 shown in FIG. 4 have similar numbering in FIG. 5. The first lateral axis 502 and the second lateral axis 504 are shown for reference. FIG. 5B shows a plurality of flow arrows where only four have been labeled for clarity, and herein refer to the fluid flow 501.

In some embodiments, the thermally active region 564 includes a first flow barrier 503 and a second flow barrier 505 (neither shown in FIG. 5A). The first flow barrier 503 and the second flow barrier 505 are walls that extend from the first fluid channel 584 to the second fluid channel 588 parallel to the second lateral axis 504. The first flow barrier 503 and the second flow barrier 505 also extend from the active area bottom surface 554 to the active area upper surface 150 of the top wall 140 (see FIG. 1B) along the third axis 158 (see FIG. 1B). As such, in some embodiments, the first flow barrier 503 and the second flow barrier 505 are in contact with the active area upper surface 150 of the top wall 140 and the active area bottom surface 554. In some embodiments, the first flow barrier 503 and the second flow barrier 505 at least partially define the inlet plenum 578 and the outlet plenum 592 along the edges of the inlet plenum 578 and the outlet plenum 592 parallel to the second lateral axis 504. In some embodiments, each of the first flow barrier 503 and the second flow barrier 505 is a fin 566. The fluid flow 501 in the thermally active region 564 is fluidly sealed by the active area upper surface 150 of the top wall 140, the bottom wall 552, and the side wall 162 when resident within the peripheral channel 582.

The fluid flow 501 enters the thermally active region 564 from the cooling fluid inlet channel 118 via the first fluid aperture 142 (see FIGS. 1A-1C) into the inlet plenum 578. A first portion of the fluid flow 501 is channeled by the first flow barrier 503 and the second flow barrier 505 through a first fin flow region 507 that includes a plurality of fins 566 with flow channels therebetween (not shown) into the first fluid channel 584. The first fin flow region 507 is oriented such that the direction of the channeling of the fluid through the first fin flow region 507 is parallel to the second lateral axis 504. The fluid flow 501 is in thermal contact with the first flow area 580 that defines a portion of the active area bottom surface 554. The active area bottom surface 554 is a portion of the bottom wall 552 directly opposite the body-to-heat generating device interface 156 (see FIG. 1B) across the bottom wall 552. As such, heat transfer from the heat generating device 160 (see FIG. 1B) into the fluid flow 501 is initiated as the fluid flow 501 enters the thermally active region 564. In addition, since the fins 566 of the first fin flow region 507 are in direct contact with the active area bottom surface 554, further heat transfer into the fluid flow 501 is facilitated.

In some embodiments, a second portion of the fluid flow 501 is channeled by the first flow barrier 503 and the second flow barrier 505 through a second fin flow region 509 that includes a plurality of fins 566 with flow channels therebetween (not shown) into the outlet plenum 592. The second fin flow region 509 is oriented such that the direction of the channeling of the fluid through the second fin flow region 509 is parallel to the second lateral axis 504. Since the fins 566 of the second fin flow region 509 are in direct contact with the active area bottom surface 554, further heat transfer into the fluid flow 501 is facilitated.

The fluid flow 501 that is channeled through the first fin flow region 507 is channeled to first fluid channel 584 where the fluid flow 501 is in thermal contact with the second flow area 586 that defines a portion of the active area bottom surface 554. The active area bottom surface 554 is a portion of the bottom wall 552 directly opposite the body-to-heat generating device interface 156 (see FIG. 1B) across the bottom wall 552. As such, heat transfers from the heat generating device 160 (see FIG. 1B) into the fluid flow 501 as the fluid flow 501 enters the first fluid channel 584. In addition, the first fluid channel 584 facilitates mixing of the fluid flow 501 exiting the first fin flow region 507. The fluid flow 501 in the first fluid channel 584 is channeled in a direction parallel to the first lateral axis 502 in both directions, i.e., to the left toward a third fin flow region 511 and to the right toward a fourth fin flow region 513. The fluid flow 501 is channeled into the third fin flow region 511 at least partially by the first flow barrier 503. The fluid flow 501 is also channeled into the fourth fin flow region 513 at least partially by the second flow barrier 505.

In some embodiments, the fluid flow 501 is channeled by the first flow barrier 503 from the first fluid channel 584 through the third fin flow region 511 that includes a plurality of fins 566 with flow channels therebetween (not shown) into the second fluid channel 588. Similarly, the fluid flow 501 is channeled by the second flow barrier 505 from the first fluid channel 584 through fourth fin flow region 513 that includes a plurality of fins 566 with flow channels therebetween (not shown) into the second fluid channel 588. The third fin flow region 507 and the fourth fin flow region 511 are oriented such that the direction of the channeling of the fluid through the third fin flow region 511 and the fourth fin flow region 513 is parallel to the second lateral axis 504. Since the fins 566 of the third fin flow region 511 and the fourth fin flow region 513 are in direct contact with the active area bottom surface 554, further heat transfer into the fluid flow 501 is facilitated.

The fluid flow 501 that is channeled through the third fin flow region 511 and the fourth fin flow region 513 is channeled to second fluid channel 588 where the fluid flow 501 is in thermal contact with the third flow area 590 that defines a portion of the active area bottom surface 554. The active area bottom surface 554 is a portion of the bottom wall 552 directly opposite the body-to-heat generating device interface 156 (see FIG. 1B) across the bottom wall 552. As such, heat transfers from the heat generating device 160 (see FIG. 1B) into the fluid flow 501 as the fluid flow 501 enters the second fluid channel 588. In addition, the second fluid channel 588 facilitates mixing of the fluid flow 501 exiting the third fin flow region 511 and the fourth fin flow region 513. The fluid flow 501 in the second fluid channel 588 is channeled in a direction parallel to the first lateral axis 502 in both directions, i.e., to the right from the third fin flow region 511 and to the left from the fourth fin flow region 513. The fluid flow 501 is channeled into a fifth fin flow region 515.

In some embodiments, the fluid flow 501 is channeled from the second flow channel 588 through the fifth fin flow region 515 that includes a plurality of fins 566 with flow channels therebetween (not shown) into the outlet plenum 592. The fifth fin flow region 515 is oriented such that the direction of the channeling of the fluid through the fifth fin flow region 515 is parallel to the second lateral axis 504. Since the fins 566 of the fifth fin flow region 515 are in direct contact with the active area bottom surface 554, further heat transfer into the fluid flow 501 is facilitated. As the fluid flow 501 enters the outlet plenum 592, the fluid flow 501 is in thermal contact with the fourth flow area 594 that defines a portion of the active area bottom surface 554. The active area bottom surface 554 is a portion of the bottom wall 552 directly opposite the body-to-heat generating device interface 156 (see FIG. 1B) across the bottom wall 552. As such, heat transfer from the heat generating device 160 (see FIG. 1B) into the fluid flow 501 occurs as the fluid flow 501 enters the outlet plenum 592. Subsequently, the fluid flow 501 exits the thermally active region 564 into the cooling fluid outlet channel 128 via the second fluid aperture 144 (see FIGS. 1A-1C) from the outlet plenum 592.

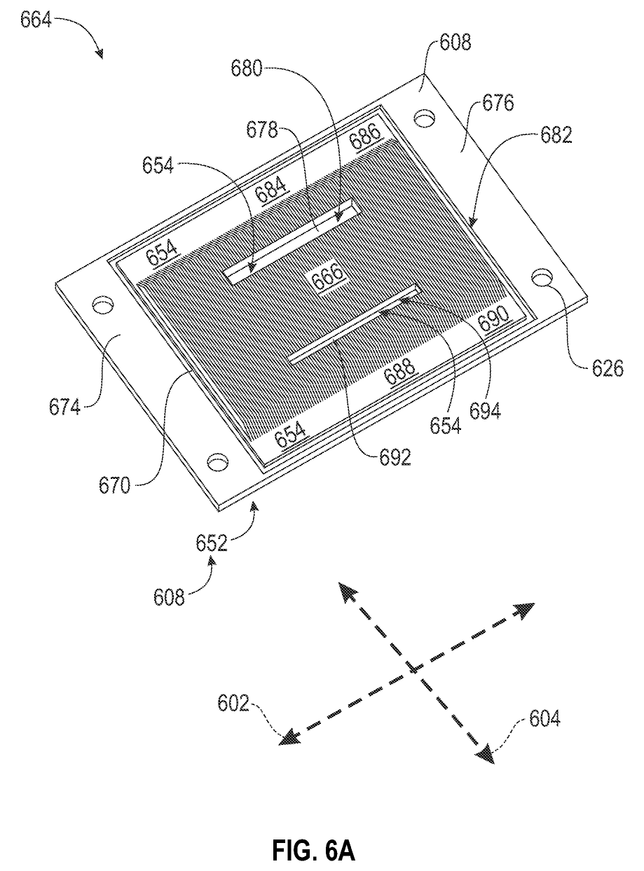

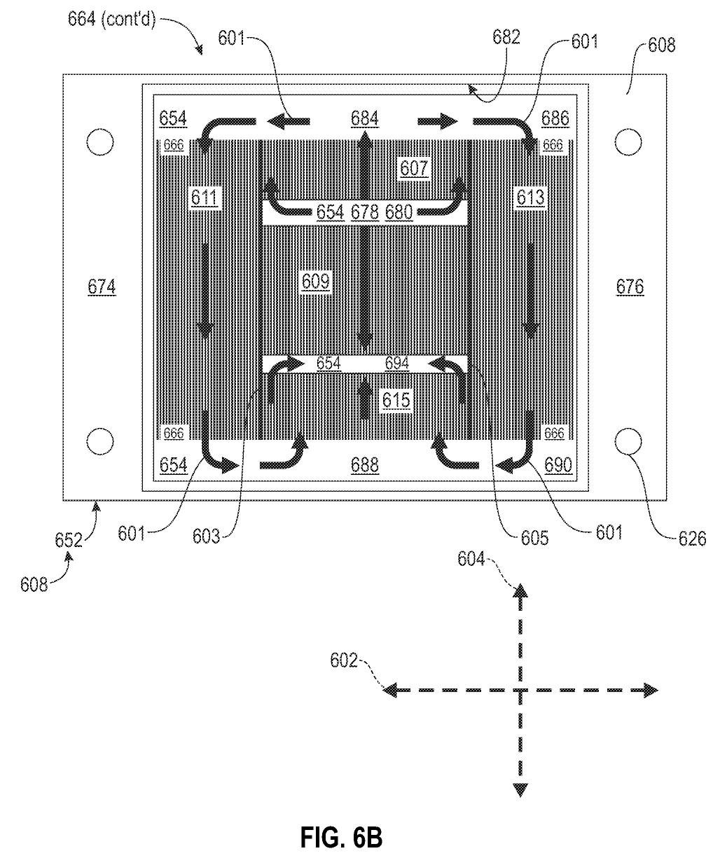

Referring to FIG. 6A, a block schematic diagram is presented illustrating a portion of a device configured to remove heat from electronic devices from an isometric perspective, in accordance with some embodiments of the present disclosure. In at least some embodiments, the portion of the device is the thermally active region 664 (described as the thermally active region 564 with respect to FIGS. 5A and 5B). Accordingly, similar to FIG. 5A, FIG. 6A illustrates a portion of the device 100 (see FIG. 1B) with the first fluid riser 110, the second fluid riser 120. the top wall 140 (including the lid surface 146), and the side wall 162 removed to show the thermally active region 664. In addition to the device 100, in some embodiments, the thermally active region 664 is configured for use with any one of the devices 200, 300, and 400 as shown in FIGS. 2-4, respectively. Those components of the thermally active region 664 that are similar to those components of the device 100 shown in FIGS. 1A-1C, the device 200 shown in FIG. 2, the device 300 shown in FIG. 3, the device 400 shown in FIG. 4, and the thermally active region 564 shown in FIG. 5A have similar numbering in FIG. 6A. The first lateral axis 602 and the second lateral axis 604 are shown for reference.

In one or more embodiments, the thermally active region 664 is similar to the thermally active region 564 as discussed with respect to FIG. 5A, with the exceptions as discussed further. Therefore, those components of the thermally active region 664 that are similar to those components of the thermally active region 564 shown in FIG. 5A have similar numbering in FIG. 6A. In contrast to the thermally active region 564, where the fourth flow area 594 of the outlet plenum 592 has the same dimensions as the first flow area 580 of the inlet plenum 578, the inlet plenum 678 in FIG. 6A has a greater first flow area 680 than the fourth flow area 694 of the outlet plenum 692. In some embodiments, the smaller fourth flow area 694 (as compared to the first flow area 680) will induce a throttling effect on the fluid exiting the thermally active region 664. Such throttling effect facilitates slowing the fluid transport through the thermally active region 664, which in turn facilitates increased heat transfer into each unit of the fluid as it traverses the thermally active region 664. In addition, the fluid entering through the inlet plenum 678 will have a greater velocity than the fluid leaving though the outlet plenum 692 due to the head loss of the fluid as it transits through the thermally active region 664. Therefore, for such embodiments, a smaller sizing for the outlet plenum 692 will be sufficient to maintain proper flow therethrough. The lesser removal of the respective fins for the outlet plenum 692 facilitates lower cost of fabrication of the thermally active region 664. Accordingly, the predetermined sizing of the inlet plenum 678 and the outlet plenum 692 facilitates providing the predetermined flow distribution characteristics through the thermally active region 664.

Referring to FIG. 6B, a block schematic diagram is presented illustrating the portion of the device shown in FIG. 6A, in accordance with some embodiments of the present disclosure. In at least some embodiments, the portion of the device is the thermally active region 664. Accordingly, FIG. 6B illustrates fluid flow 601 through a portion of the device 100 (see FIG. 1B) with the first fluid riser 110, the second fluid riser 120. the top wall 140 (including the lid surface 146 and the active area upper surface 150), and the side wall 162 removed to show the thermally active region 664. In addition to the device 100, in some embodiments, the thermally active region 664 is configured for use with any one of the devices 200, 300, and 400 as shown in FIGS. 2-4, respectively. Those components of the thermally active region 664 that are similar to those components of the device 100 shown in FIGS. 1A-1C, the device 200 shown in FIG. 2, the device 300 shown in FIG. 3, the device 400 shown in FIG. 4, and the thermally active region 564 shown in FIG. 5B have similar numbering in FIG. 6B. The first lateral axis 602 and the second lateral axis 604 are shown for reference.

In one or more embodiments, the paths of fluid flows 601 through the thermally active region 664 are similar to those discussed with respect to the thermally active region 564. However, the overall flow characteristics of the thermally active region 664 are different from those discussed with respect to the thermally active region 564. Specifically, the smaller fourth flow area 694 as compared to the first flow area 680 facilitates inducing a throttling effect on the fluid flow 601 exiting the thermally active region 664. In some embodiments, slowing the fluid transport through the thermally active region 664 facilitates increased heat transfer into each unit of the fluid flow 601 as it traverses the thermally active region 664 as compared to the thermally active region 564. As such, in some embodiments, the heat transfer efficiency as a function of fluid usage is improved. In addition, in some embodiments, such throttling increases the backpressure at the inlet plenum 678 such that fluid flow 601 may be diverted to other devices 100, 200, 300, or 400. Accordingly, the predetermined sizing of the inlet plenum 678 and the outlet plenum 692 facilitates providing the predetermined flow distribution characteristics through the thermally active region 664.

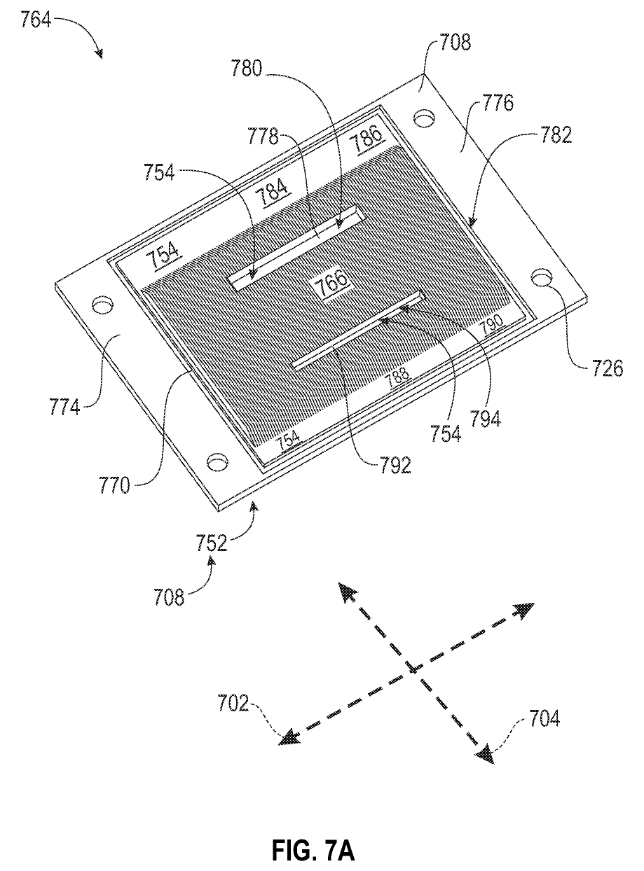

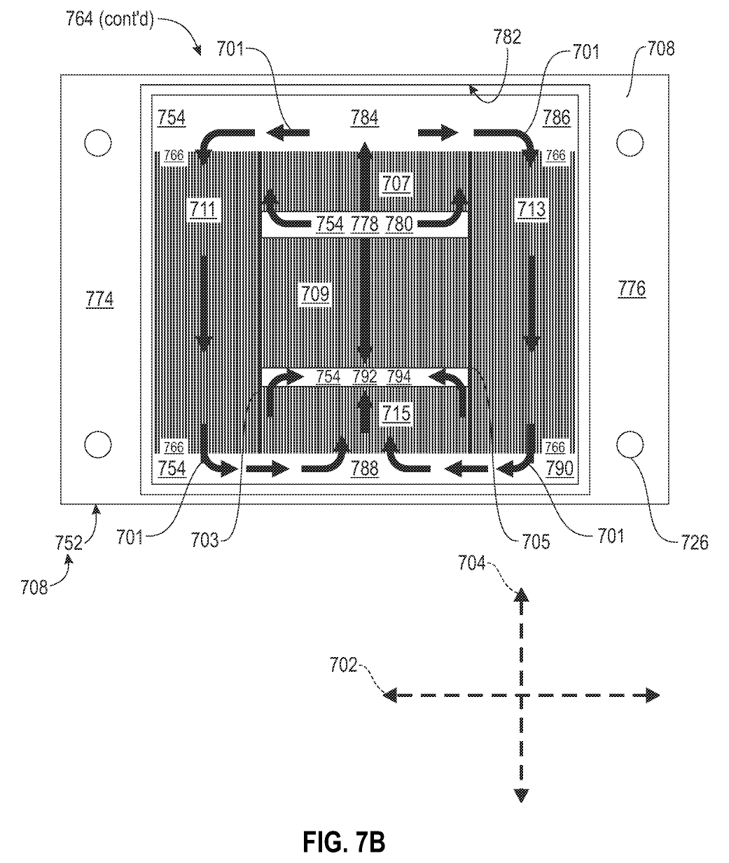

Referring to FIG. 7A, a block schematic diagram is presented illustrating a portion of a device configured to remove heat from electronic devices from an isometric perspective, in accordance with some embodiments of the present disclosure. In at least some embodiments, the portion of the device is the thermally active region 764 (described as the thermally active region 664 with respect to FIGS. 6A and 6B). Accordingly, similar to FIG. 6A, FIG. 7A illustrates a portion of the device 100 (see FIG. 1B) with the first fluid riser 110, the second fluid riser 120. the top wall 140 (including the lid surface 146), and the side wall 162 removed to show the thermally active region 564. In addition to the device 100, in some embodiments, the thermally active region 664 is configured for use with any one of the devices 200, 300, and 400 as shown in FIGS. 2-4, respectively. Those components of the thermally active region 664 that are similar to those components of the device 100 shown in FIGS. 1A-1C, the device 200 shown in FIG. 2, the device 300 shown in FIG. 3, the device 400 shown in FIG. 4, the thermally active region 564 shown in FIG. 5A, and the thermally active region 664 shown in FIG. 6A have similar numbering in FIG. 7A. The first lateral axis 702 and the second lateral axis 704 are shown for reference.

In one or more embodiments, the thermally active region 764 is similar to the thermally active region 664 as discussed with respect to FIG. 6A, with the exceptions as discussed further. Therefore, those components of the thermally active region 764 that are similar to those components of the thermally active region 664 shown in FIG. 6A have similar numbering in FIG. 7A. In contrast to the thermally active region 664, where the second flow area 686 of the first fluid channel 684 has the same dimensions as the third flow area 690 of the second fluid channel 688, the second flow area 786 of the first fluid channel 784 has a greater value than the third flow area 790 of the second fluid channel 788. In some embodiments, the smaller third flow area 790 (as compared to the second flow area 786) will induce a throttling effect on the fluid channeled through the thermally active region 764. Such throttling effect facilitates slowing the fluid transport through the thermally active region 764, which in turn facilitates increased heat transfer into each unit of the fluid as it traverses the thermally active region 764. As such, in some embodiments, the heat transfer efficiency as a function of fluid usage is improved. In addition, in some embodiments, such throttling increases the backpressure at the inlet plenum 778 such that fluid may be diverted to other devices 100, 200, 300, or 400. Accordingly, the predetermined sizing of the first fluid channel 784 and the second fluid channel 788 facilitates providing the predetermined flow distribution characteristics through the thermally active region 764.

Referring to FIG. 7B, a block schematic diagram is presented illustrating the portion of the device shown in FIG. 7A, in accordance with some embodiments of the present disclosure. In at least some embodiments, the portion of the device is the thermally active region 764. Accordingly, FIG. 7B illustrates fluid flow 701 through a portion of the device 100 (see FIG. 1B) with the first fluid riser 110, the second fluid riser 120. the top wall 140 (including the lid surface 146 and the active area upper surface 150), and the side wall 162 removed to show the thermally active region 664. In addition to the device 100, in some embodiments, the thermally active region 664 is configured for use with any one of the devices 200, 300, and 400 as shown in FIGS. 2-4, respectively. Those components of the thermally active region 764 that are similar to those components of the device 100 shown in FIGS. 1A-1C, the device 200 shown in FIG. 2, the device 300 shown in FIG. 3, the device 400 shown in FIG. 4, and the thermally active region 664 shown in FIG. 6B have similar numbering in FIG. 7B. The first lateral axis 702 and the second lateral axis 704 are shown for reference.

In one or more embodiments, the paths of fluid flows 701 through the thermally active region 764 are similar to those discussed with respect to the thermally active region 664. However, the overall flow characteristics of the thermally active region 764 are different from those discussed with respect to the thermally active region 664. Specifically, the smaller third flow area 790 as compared to the second flow area 786 facilitates inducing a throttling effect on the fluid flow 701 flowing through the thermally active region 764. In some embodiments, slowing the fluid transport through the thermally active region 764 facilitates increased heat transfer into each unit of the fluid flow 701 as it traverses the thermally active region 764 as compared to the thermally active region 664. As such, in some embodiments, the heat transfer efficiency as a function of fluid usage is improved. In addition, in some embodiments, such throttling increases the backpressure at the inlet plenum 778 such that fluid flow 701 may be diverted to other devices 100, 200, 300, or 400. Accordingly, the predetermined sizing of the first fluid channel 784 and the second fluid channel 788 facilitates providing the predetermined flow distribution characteristics through the thermally active region 764.

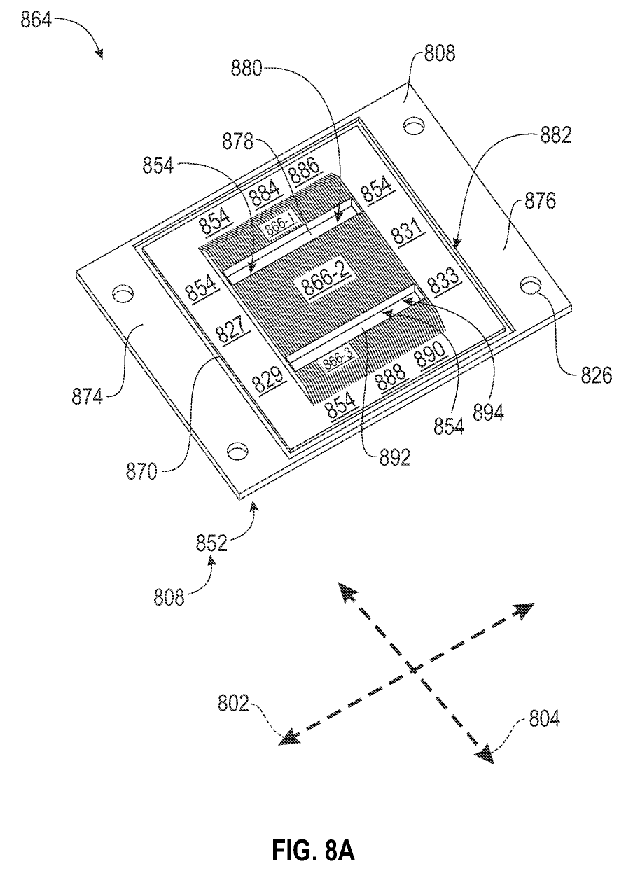

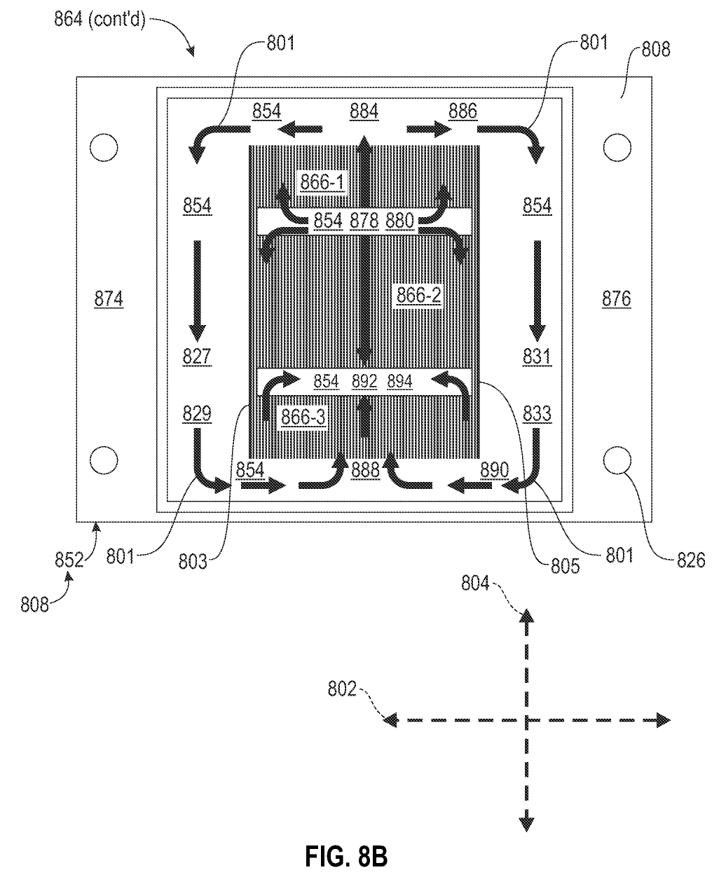

Referring to FIG. 8A, a block schematic diagram is presented illustrating a portion of a device configured to remove heat from electronic devices from an isometric perspective, in accordance with some embodiments of the present disclosure. In at least some embodiments, the portion of the device is the thermally active region 864 (described as the thermally active region 564 with respect to FIGS. 5A and 5B). Accordingly, similar to FIG. 5A, FIG. 8A illustrates a portion of the device 100 (see FIG. 1B) with the first fluid riser 110, the second fluid riser 120. the top wall 140 (including the lid surface 146), and the side wall 162 removed to show the thermally active region 864. In addition to the device 100, in some embodiments, the thermally active region 864 is configured for use with any one of the devices 200, 300, and 400 as shown in FIGS. 2-4, respectively. Those components of the thermally active region 864 that are similar to those components of the device 100 shown in FIGS. 1A-1C, the device 200 shown in FIG. 2, the device 300 shown in FIG. 3, the device 400 shown in FIG. 4, and the thermally active region 564 shown in FIG. 5A have similar numbering in FIG. 8A. The first lateral axis 802 and the second lateral axis 804 are shown for reference.

In one or more embodiments, the thermally active region 864 is similar to the thermally active region 564 as discussed with respect to FIG. 5A, with the exceptions as discussed further. Therefore, those components of the thermally active region 864 that are similar to those components of the thermally active region 564 shown in FIG. 5A have similar numbering in FIG. 8A.

In some embodiments, similar to the thermally active region 564 that has the plurality of fins 566 with flow channels therebetween separated into five distinct fin flow regions 507-515 with a substantially similar fin pitch (i.e., separation), thermally active region 864 includes three fin flow regions with similar fin pitches. Specifically, the thermally active region 864 includes a first fin flow region 866-1, a second fin flow region 866-2, and a third fin flow region 866-3.

In one or more embodiments, the thermally active region 864 includes a third fluid channel 827 that defines a fifth flow area 829 of the active area bottom surface 854 exposed to the fluid. In addition, the thermally active region 864 includes a fourth fluid channel 831 that defines a sixth flow area 833 of the active area bottom surface 854 exposed to the fluid. In some embodiments, at least some of the dimensions of the third fluid channel 827 and the fourth fluid channel 831 differ from the respective dimensions of the first fluid channel 884 and the second fluid channel 888. In some embodiments, the third fluid channel 827 and the fourth fluid channel 831 are similar to the first fluid channel 884 and the second fluid channel 888 with the following additional exceptions.

In at least some embodiments, the third fluid channel 827 and the fourth fluid channel 831 are coupled in flow communication with the first fluid channel 884 and the second fluid channel 888. In some embodiments, the third fluid channel 827 and the fourth fluid channel 831 are rectangular heat transfer flow distribution regions that are oriented with the long dimension extending parallel to the second lateral axis 804 and the short dimension extending parallel to the first lateral axis 802. As such, the third fluid channel 827 and the fourth fluid channel 831 are oriented parallel to each other and perpendicular with the first fluid channel 884 and the second fluid channel 888. In some embodiments, the third fluid channel 827 and the fourth fluid channel 831 have any shape and configuration that enables operation of the thermally active region 864 as described herein. The third fluid channel 827 and the fourth fluid channel 831 are lateral peripheral flow regions that define the fifth flow area 829 and the sixth flow area 833, respectively, extending along a portion of the peripheral channel 882. As with the first fluid channel 884 and the second fluid channel 888, the third fluid channel 827 and the fourth fluid channel 831 are fluidly sealed by a portion of the fins in the fin flow regions 866-1, 866-2, 866-3, the side wall 162, and the top wall 140 (see FIG. 1B).

In some embodiments, the third fluid channel 827 and the fourth fluid channel 831 are fabricated through removing a predetermined portion of the respective fins through any mechanism that enables operation of the thermally active region 864 as described herein, including, without limitation, mechanical grinding and chemical etching. In some embodiments, the fins in the predetermined region are reduced to a predetermined height less than the full height of the fins. In some embodiments, the fins in the predetermined regions are completely removed. In some embodiments, the third fluid channel 827 and the fourth fluid channel 831 are formed by coupling the fins to the active area bottom surface 854 of the bottom wall 852 in a predetermined pattern that define third fluid channel 827 and the fourth fluid channel 831. As such, the fifth flow area 829 and the sixth flow area 833 define the respective portions of the active area bottom surface 854 exposed to the fluid. The dimensions of the third fluid channel 827 and the fourth fluid channel 831 include, respectively, the fifth flow area 829 and the sixth flow area 833, and the height of the fins (not shown).

The third fluid channel 827 and the fourth fluid channel 831 are each configured to receive a portion of the fluid from the first fluid channel 884 and channel the fluid to the second fluid channel 888. As such, the fluid that has been channeled about the fins in the first fin flow region 866-1 is distributed to the third fluid channel 827 and the fourth fluid channel 831 for channeling to the second fluid channel 888. The fluid is channeled from the second fluid channel 888 to the fins of the third fin flow region 866-3. The fluid in the third fluid channel 827 and the fourth fluid channel 831 are in direct contact with the active area bottom surface 854 and capture the heat therefrom.

A portion of the fluid is channeled from the inlet plenum 878 toward the outlet plenum 892 across the second fin flow region 866-2. In some embodiments, the resistance to flow is lower for the third fluid channel 827 and the fourth fluid channel 831 than the resistance to flow of the second fin flow region 866-2, thereby inducing the desire flow patterns in the thermally active region 864. The flows of the fluid through the thermally active region 864 are discussed further with respect to FIG. 8B. Accordingly, the addition of the third fluid channel 827 and the fourth fluid channel 831 provide the flow distribution characteristics to the fluid that facilitate the overall flow distribution through the thermally active region 864.

Referring to FIG. 8B, a block schematic diagram is presented illustrating the portion of the device shown in FIG. 8A, in accordance with some embodiments of the present disclosure. In at least some embodiments, the portion of the device is the thermally active region 864. Accordingly, FIG. 8B illustrates fluid flow through a portion of the device 100 (see FIG. 1B) with the first fluid riser 110, the second fluid riser 120. the top wall 140 (including the lid surface 146 and the active area upper surface 150), and the side wall 162 removed to show the thermally active region 864. In addition to the device 100, in some embodiments, the thermally active region 864 is configured for use with any one of the devices 200, 300, and 400 as shown in FIGS. 2-4, respectively. Those components of the thermally active region 864 that are similar to those components of the device 100 shown in FIGS. 1A-1C, the device 200 shown in FIG. 2, the device 300 shown in FIG. 3, the device 400 shown in FIG. 4, and the thermally active region 564 shown in FIG. 5B have similar numbering in FIG. 8B. The first lateral axis 802 and the second lateral axis 804 are shown for reference.

In one or more embodiments, a portion of the paths of fluid flows 801 through the thermally active region 864 are similar to those discussed with respect to the thermally active region 564. However, the overall flow characteristics of the thermally active region 864 are different from those discussed with respect to the thermally active region 564.

The flow of the fluid flow 801 proceeds from the first fin flow region 866-1 into the first fluid channel 884. The fluid flow 801 is channeled into the third fluid channel 827 and the fourth fluid channel 831. The fluid in the third fluid channel 827 and the fourth fluid channel 831 are in direct contact with the active area bottom surface 854 and capture the heat therefrom. The fluid flow 801 then flows into the second fluid channel 888. The fluid flow 801 is channeled from the second fluid channel 888 to the fins of the third fin flow region 866-3.

In at least some embodiments, a portion of the fluid flow 801 is channeled from the inlet plenum 878 toward the outlet plenum 892 across the second fin flow region 866-2. In some embodiments, the resistance to flow is lower for the third fluid channel 827 and the fourth fluid channel 831 than the resistance to flow of the second fin flow region 866-2, thereby inducing the desire flow patterns in the thermally active region 864. Accordingly, the addition of the third fluid channel 827 and the fourth fluid channel 831 provide the flow distribution characteristics to the fluid that facilitate the overall flow distribution through the thermally active region 864.

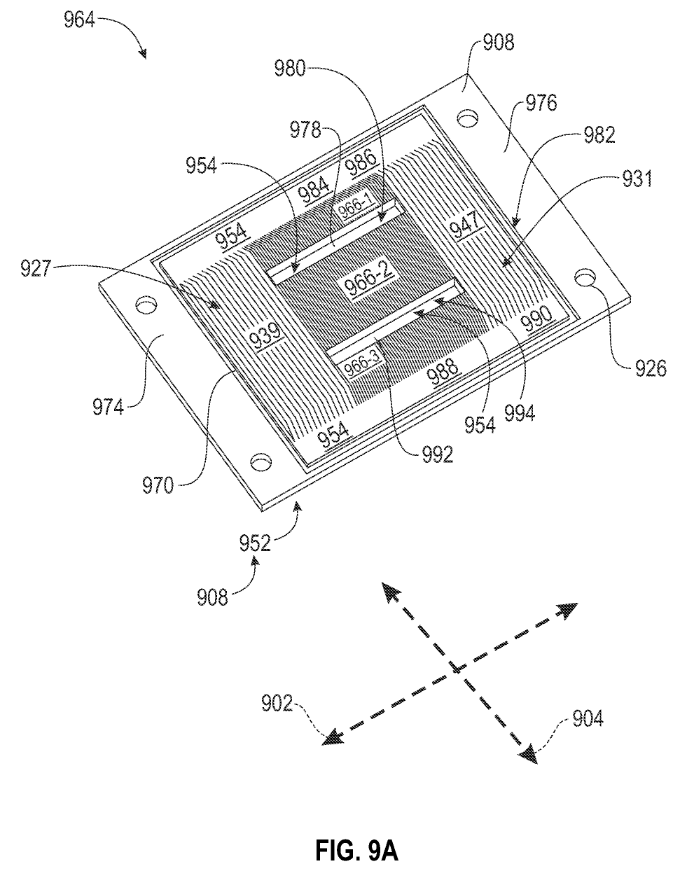

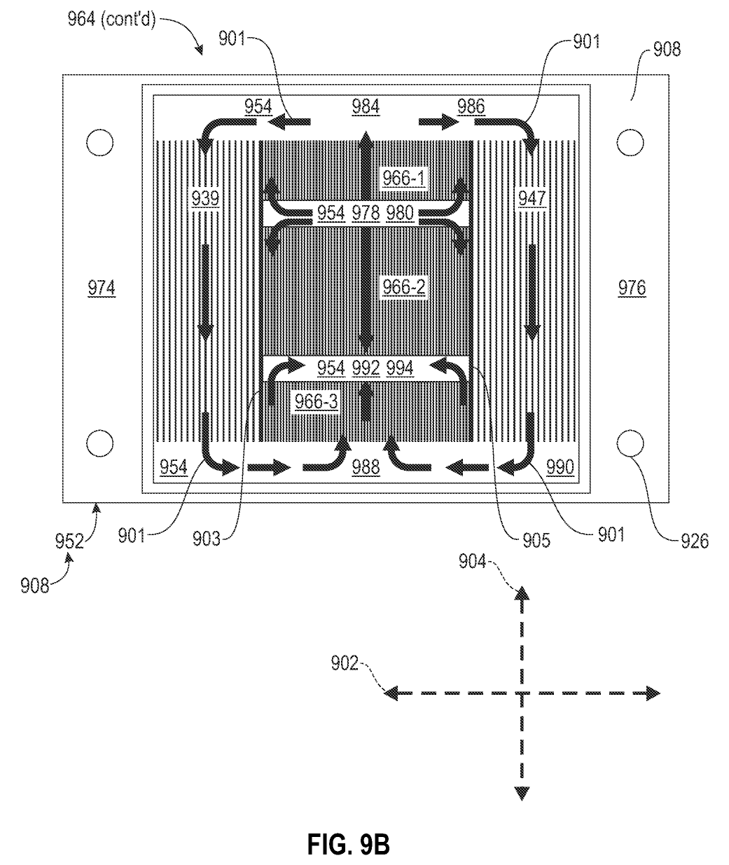

Referring to FIG. 9A, a block schematic diagram is presented illustrating a portion of a device configured to remove heat from electronic devices from an isometric perspective, in accordance with some embodiments of the present disclosure. In at least some embodiments, the portion of the device is the thermally active region 964 (described as the thermally active region 864 with respect to FIGS. 8A and 8B). Accordingly, similar to FIG. 8A, FIG. 9A illustrates a portion of the device 100 (see FIG. 1B) with the first fluid riser 110, the second fluid riser 120. the top wall 140 (including the lid surface 146), and the side wall 162 removed to show the thermally active region 964. In addition to the device 100, in some embodiments, the thermally active region 964 is configured for use with any one of the devices 200, 300, and 400 as shown in FIGS. 2-4, respectively. Those components of the thermally active region 964 that are similar to those components of the device 100 shown in FIGS. 1A-1C, the device 200 shown in FIG. 2, the device 300 shown in FIG. 3, the device 400 shown in FIG. 4, and the thermally active region 864 shown in FIG. 8A have similar numbering in FIG. 9A. The first lateral axis 902 and the second lateral axis 904 are shown for reference.

In one or more embodiments, the thermally active region 964 is similar to the thermally active region 864 as discussed with respect to FIG. 8A, with the exceptions as discussed further. Therefore, those components of the thermally active region 964 that are similar to those components of the thermally active region 864 shown in FIG. 8A have similar numbering in FIG. 9A.

In some embodiments, the thermally active region 964 includes the first fin flow region 966-1, the second fin flow region 966-2, and the third fin flow region 966-3. The fin flow regions 966-1, 966-2, and 966-3 have a first fin pitch. Accordingly, in some embodiments, the first fin pitch has any values that enable operation of the thermally active region 964 as described herein.

In one or more embodiments, the third fluid channel 827 and the fourth fluid channel 831 of FIGS. 8A and 8B are overlaid with fins (using any of the mechanisms previously discussed) to define a first finned channel 927 and a second finned channel 931. The first finned channel 927 defines a fourth fin flow region 939 with the second fin pitch. In some embodiments, the fourth fin flow region 939 includes a fin pitch that is any value that enables operation of the thermally active region 964 as described herein. Similarly, the second finned channel 931 defines a fifth fin flow region 947 with a third fin pitch. In some embodiments, the fifth fin flow region 947 includes a fin pitch that is any value that enables operation of the thermally active region 964 as described herein. In some embodiments, the second and third fin pitches are similar. In some embodiments, the second and third fin pitches are different. In some embodiments, the second and third fin pitches are different than the first pitch. Accordingly, the pattern of the fluid flow throughout the thermally active region 964 is assigned with a predetermined operational configuration including the various fin pitches defined in the respective flow regions with fins.

The flows of the fluid through the thermally active region 964 are discussed further with respect to FIG. 9B. Accordingly, the addition of the first finned channel 927 and the second finned channel 931 in conjunction with the varying pitch of the fins associated with the first finned channel 927 and the second finned channel 931 provides the flow distribution characteristics to the fluid that facilitate the overall flow distribution through the thermally active region 964.

Referring to FIG. 9B, a block schematic diagram is presented illustrating the portion of the device shown in FIG. 9A, in accordance with some embodiments of the present disclosure. In at least some embodiments, the portion of the device is the thermally active region 964. Accordingly, FIG. 9B illustrates fluid flow through a portion of the device 100 (see FIG. 1B) with the first fluid riser 110, the second fluid riser 120. the top wall 140 (including the lid surface 146 and the active area upper surface 150), and the side wall 162 removed to show the thermally active region 964. In addition to the device 100, in some embodiments, the thermally active region 964 is configured for use with any one of the devices 200, 300, and 400 as shown in FIGS. 2-4, respectively. Those components of the thermally active region 964 that are similar to those components of the device 100 shown in FIGS. 1A-1C, the device 200 shown in FIG. 2, the device 300 shown in FIG. 3, the device 400 shown in FIG. 4, and the thermally active region 864 shown in FIG. 8B have similar numbering in FIG. 9B. The first lateral axis 902 and the second lateral axis 904 are shown for reference.

In one or more embodiments, a portion of the paths of fluid flows 901 through the thermally active region 964 are similar to those discussed with respect to the thermally active region 864. However, the overall flow characteristics of the thermally active region 964 are different from those discussed with respect to the thermally active region 864. Specifically, for those embodiments that include the first finned channel 927 and the second finned channel 931 as described with respect to FIG. 9A the characteristics and patterns of the fluid flow 901 are different from the fluid flow 801.

Accordingly, the replacement of the third fluid channel 827 and the fourth fluid channel 831 with the first finned channel 927 and the second finned channel 931 that include the previously discussed varying pitches of the fins associated with the fin flow regions 966-1, 966-2, and 966-3, and 939 and 947 that are configured to provide the flow distribution characteristics to the fluid flow 901 that facilitate the overall flow distribution through the thermally active region 964.

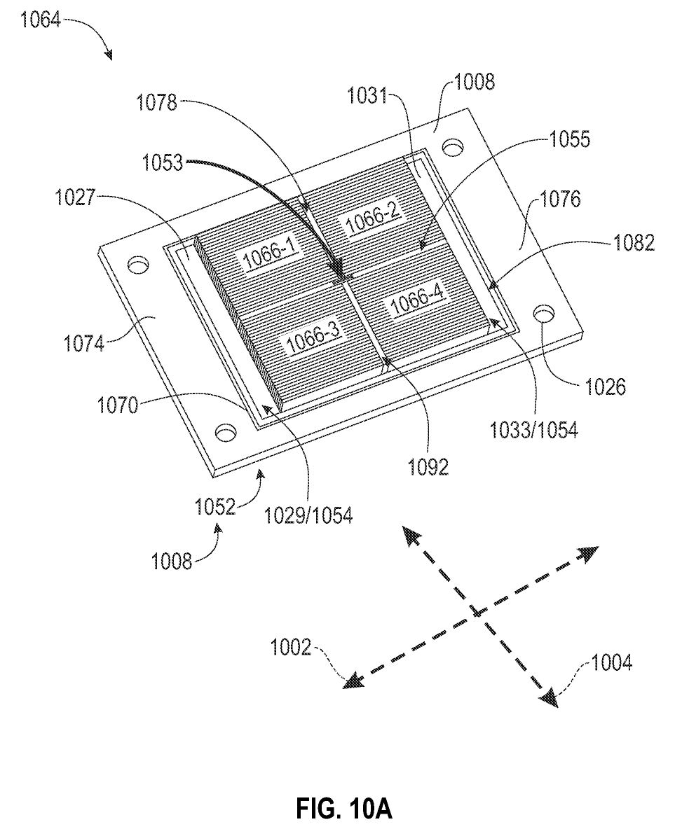

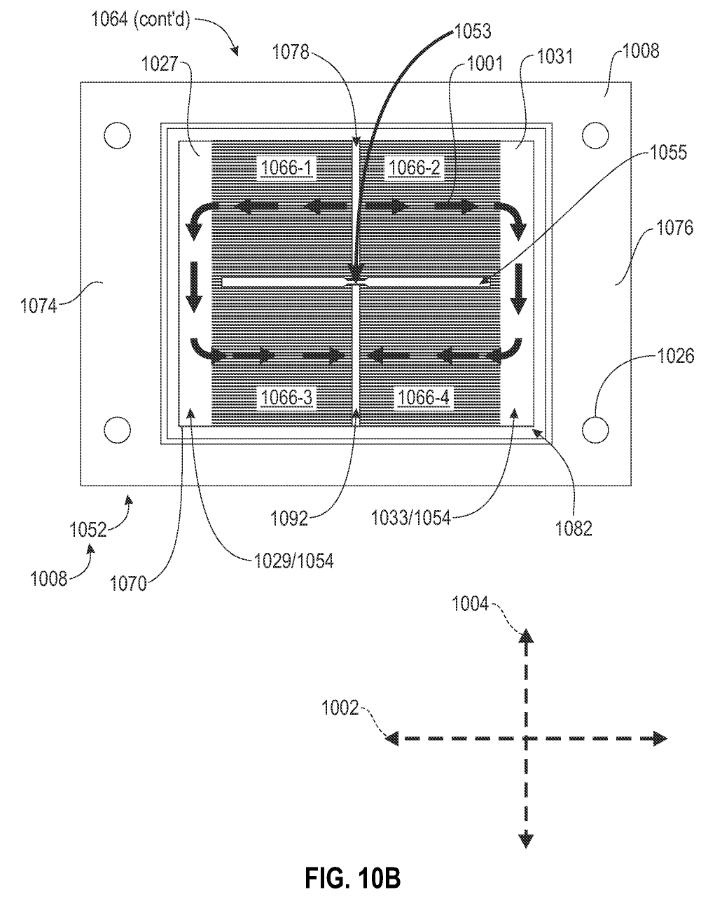

Referring to FIG. 10A, a block schematic diagram is presented illustrating a portion of a device configured to remove heat from electronic devices from an isometric perspective, in accordance with some embodiments of the present disclosure. In at least some embodiments, the portion of the device is the thermally active region 1064 (described as the thermally active region 864 with respect to FIGS. 8A and 8B). Accordingly, similar to FIG. 8A, FIG. 10A illustrates a portion of the device 100 (see FIG. 1B) with the first fluid riser 110, the second fluid riser 120. the top wall 140 (including the lid surface 146), and the side wall 162 removed to show the thermally active region 1064. In addition to the device 100, in some embodiments, the thermally active region 1064 is configured for use with any one of the devices 200, 300, and 400 as shown in FIGS. 2-4, respectively. Those components of the thermally active region 1064 that are similar to those components of the device 100 shown in FIGS. 1A-1C, the device 200 shown in FIG. 2, the device 300 shown in FIG. 3, the device 400 shown in FIG. 4, and the thermally active region 864 shown in FIG. 8A have similar numbering in FIG. 10A. The first lateral axis 1002 and the second lateral axis 1004 are shown for reference.

The thermally active region 1064 includes an inlet plenum 1078 and an outlet plenum 1092 separated by a plenum wall 1053. The thermally active region 1064 also includes a first fin flow region 1066-1, a second fin flow region 1066-2, a third fin flow region 1066-3, and a fourth fin flow region 1066-4. In some embodiments, the first fin flow region 1066-1, the second fin flow region 1066-2, the third fin flow region 1066-3, and the fourth fin flow region 1066-4 have similar dimensions. In some embodiments, one or more of the four fin flow regions 1066-1 have different dimensions.

In some embodiments, the fin flow regions 1066-1, 1066-2, 1066-3, and 1066-4 have a similar fin pitch. In some embodiments, portions of the fin flow regions 1066-1, 1066-2, 1066-3, and 1066-4 have different fin pitches. In some embodiments, one or more of the fin flow regions 1066-1, 1066-2, 1066-3, and 1066-4 in their entirety have differing fin pitches. A flow divider 1055 physically separates the fin flow regions 1066-1 and 1066-2 from the fin flow regions 1066-3 and 1066-4.

Referring to FIG. 10B, a block schematic diagram is presented illustrating the portion of the device shown in FIG. 10A, in accordance with some embodiments of the present disclosure. In at least some embodiments, the portion of the device is the thermally active region 1064. Accordingly, FIG. 10B illustrates fluid flow through a portion of the device 100 (see FIG. 1B) with the first fluid riser 110, the second fluid riser 120. the top wall 140 (including the lid surface 146 and the active area upper surface 150), and the side wall 162 removed to show the thermally active region 1064. In addition to the device 100, in some embodiments, the thermally active region 1064 is configured for use with any one of the devices 200, 300, and 400 as shown in FIGS. 2-4, respectively. Those components of the thermally active region 1064 that are similar to those components of the device 100 shown in FIGS. 1A-1C, the device 200 shown in FIG. 2, the device 300 shown in FIG. 3, the device 400 shown in FIG. 4, and the thermally active region 1064 shown in FIG. 10A have similar numbering in FIG. 10B. The first lateral axis 1002 and the second lateral axis 1004 are shown for reference.

In one or more embodiments, the fluid 1001 enters the thermally active region 1064 through the inlet plenum 1078. A portion of the fluid 1001 is channeled toward the first fin flow region 1066-1 and a portion of the fluid is channeled toward the second fin flow region 1066-2. The fluid 1001 channeled through the first fin flow region 1066-1 is channeled into and through the third fluid channel 1027 into the third fin flow region 1066-3 and into the outlet plenum 1092. The fluid 1001 channeled through the second fin flow region 1066-2 is channeled into and through the fourth fluid channel 1031 into the fourth fin flow region 1066-4 and into the outlet plenum 1092.

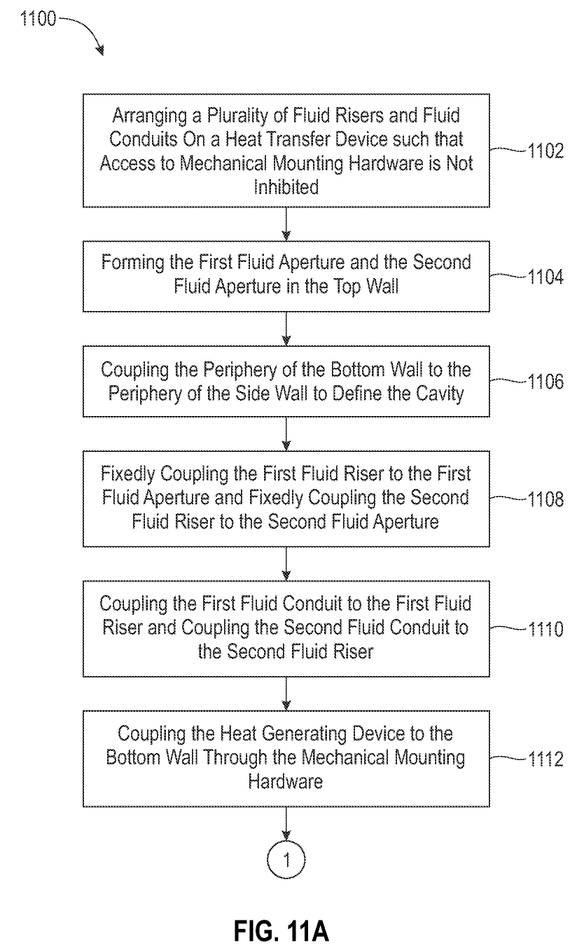

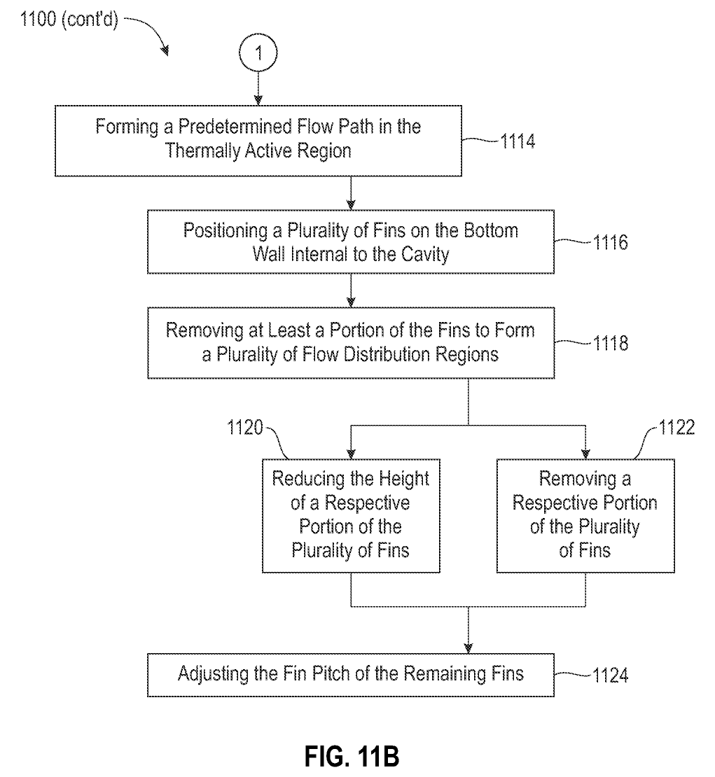

Referring to FIG. 11A, a flowchart is presented illustrating a process 1100 for manufacturing a cold plate, i.e., the device 100 that is configured to remove heat from electronic devices in accordance with some embodiments of the present disclosure. While FIG. 11A is substantially described with reference to device 100 shown in FIGS. 1A-1C, the process 1100 is also applicable to the device 200 shown in FIG. 2, the device 300 shown in FIG. 3, and the device 400 shown in FIG. 4.

In one or more embodiments, the process 1100 includes arranging a plurality of fluid risers and fluid conduits that are coupled to the device 100 such that access to the mechanical mounting hardware is not inhibited, i.e., there is no access interference of the mechanical mounting hardware caused by the fluid risers and fluid conduits. This is shown as step 1102.

In some embodiments, the step 1102 includes forming the first fluid aperture 142 and the second fluid aperture 144 in the top wall 140. This is shown as step 1104. The first fluid aperture 142 is oriented in a first direction with the first angle 130 with respect to the first lateral axis 102. The second fluid aperture 144 is oriented in a second direction with the second angle 132 with respect to the first lateral axis 102. The absolute value of the second angle 132 equals the absolute value of the first angle 130. The first fluid aperture 142 and the second fluid aperture 144 are symmetrically positioned in opposition with respect to the first lateral axis 102 and are coincident with the second lateral axis 104.

In addition, in some embodiments, the step 1102 also includes coupling the top wall 140 to the bottom wall 152 in opposition to each other. More specifically, the periphery 151 of the bottom wall 152 and the periphery 161 of the side wall 162 are coupled to each other to define the cavity 163 using any mechanism that enables the process 1100. The top wall 140 and the side wall 162 are previously coupled to each other, or are fabricated to define a unitary top wall 140 that includes the side walls 162. This is shown as step 1106. As such, the thermally active region 164 is at least partially defined for the device 100 by the cavity 163.

In some embodiments, the step 1102 further includes fixedly coupling the first fluid riser 110 to the first fluid aperture 142 and fixedly coupling the second fluid riser 120 to the second fluid aperture 144. This is shown as step 1108. As such, the first fluid riser 110 and the second fluid riser 120 are configured to not swivel. The step 1102 also includes coupling a first fluid conduit 112 to the first fluid riser 110 and coupling the second fluid conduit 122 to the second fluid riser 120. This is shown as step 1110. In some embodiments, the first fluid riser 110 and the second fluid riser 120 are oriented to receive the respective first fluid conduit 112 and the second fluid conduit 122 from the same side of the device 100. In some embodiments, the first fluid riser 110 and the second fluid riser 120 are oriented to receive the respective first fluid conduit 112 and the second fluid conduit 122 from opposite sides of the device 100.

In one or more embodiments, the process 1100 also includes coupling the heat generating device 160 to the bottom wall 152 though the mechanical mounting hardware. This is shown as step 1112.

The positioning and orientations as discussed above facilitate integration of the heat generating device 160 into a respective computing system through permitting the use of fluid conduits with larger radii and larger bend radii. As such, the increased design flexibility with respect to the size of the fluid conduits and the respective bend radii facilitates integrating larger heat generating devices 160, such as larger and more powerful processors, into computer systems. Moreover, the configuration of the device 100 and the design flexibility with respect to the routings of the cooling fluid inlet channel 118 and the cooling fluid outlet channel 128 facilitates increasing the available room within the respective servers for additional components through facilitating more efficient and effective routing of the cooling conduits therein. Furthermore, the embodiments described herein negate the need for relatively bulky and expensive fluid manifolds and the associated additional hardware typically used to provide cooling fluid supply and return to known cold plates. As such, the devices disclosed herein use a lower profile with fewer hardware pieces and lower cost, including the elimination of hose swivel fixtures. Decreasing the size of the cold plate devices facilitates server designers’ opportunities to add additional processors to the servers.

In addition, in at least some embodiments, the ease of access to the mechanical mounting hardware facilitates removal of the device 100 for inspection, maintenance, and replacement. The orientations and positions of the cooling fluid inlet channel 118 and the cooling fluid outlet channel 128 facilitate the use of the tooling used to remove the mechanical mounting hardware that is proximate the top wall 140. In addition, the configuration of the device 100, including the orientations and positions of the cooling fluid inlet channel 118 and the cooling fluid outlet channel 128 facilitate operations including, without limitation, the partial disassembly operations previously described. As such, any two adjacent fasteners 137 of the mechanical mounting hardware 125 may be removed and the other two fasteners 137 of the mechanical mounting hardware 125 loosened to at least partially lift the device 100 from one side of the device 100. Moreover, the design flexibility with respect to the routings of the cooling fluid inlet channel 118 and the cooling fluid outlet channel 128 facilitates the inclusion of additional devices on the lid surface 146 and increasing the available room within the respective servers for additional components through facilitating more efficient and effective routing of the cooling conduits therein.

Referring to FIG. 11B, a continuation of the flowchart shown in FIG. 11A is presented illustrating the process 1100 for manufacturing a cold plate, i.e., the device 100 that is configured to remove heat from electronic devices in accordance with some embodiments of the present disclosure. While FIG. 11B is substantially described with reference to the thermally active region 564 shown in FIG. 5A and 5B, the process 1100 is also applicable to the device 100 shown in FIGS. 1A-1C, the device 200 shown in FIG. 2, the device 300 shown in FIG. 3, the device 400 shown in FIG. 4, and the thermally active regions 664, 764, 864, 964, and 1064 as shown and described with respect to FIGS. 6A-10B, respectively.

In some embodiments, the process 1100 further includes forming a predetermined flow path in the thermally active region 564. This is shown as step 1114. The step 1114 includes positioning a plurality of fins 566 on the bottom wall 552 internal to the cavity 163. This is shown as step 1116. The step 1114 also includes removing at least a portion of the fins 566 to form a plurality of flow distribution regions including the inlet plenum 578, the first fluid channel 584, the second fluid channel 588, and the outlet plenum 592. This is shown as step 1118. The flow distribution regions are sized to predetermined dimensions to facilitate the predetermined flow distribution in the thermally active region 564. Step 1118 includes one or more of reducing the height of a respective portion of the plurality of fins 566 and/or removing a respective portion of the plurality of fins 566. These are shown as steps 1120 and 1122, respectively.

Further in some embodiments, the step 1114 further includes adjusting the fin pitch of at least a portion of the remaining fins 566. This is shown as step 1124. In some embodiments, the remaining fins 566 include those fins 566 that had their height lessened, but not removed.

Accordingly, the predetermined flow patterns are placed into service.

The embodiments as disclosed and described herein are configured to provide an improvement to the technological field associated with fluid cooling of electronic devices using a cold plate with a hose routing arrangement in an electronic drawer containing one or multiple printed circuit boards. The embodiments of the devices disclosed herein are configured to remove heat from the respective heat generating devices, where the devices are compact and low-profile, low-cost, with effective and efficient heat removal features. The various configurations of the devices disclosed herein present external structural configurations and orientations that include hose routing within the server drawer that facilitates easy removal to inspect or replace a heat generating device underneath, e.g., a processor. The internal structure structural configurations and orientations of the devices disclosed herein uses low-cost construction and fluid flow distribution for optimal cooling.

The embodiments described herein negate the need for relatively bulky and expensive fluid manifolds and the associated additional hardware typically used to provide cooling fluid supply and return to known cold plates. As such, the devices disclosed herein use a lower profile with fewer hardware pieces and lower cost, including the elimination of hose swivel fixtures. Decreasing the size of the cold plate devices facilitates server designers’ opportunities to add additional processors to the servers.

In addition, the embodiments presented herein with the one or more of the partial and the complete removal of fins in certain predetermined fluid flow regions defines fluid flow channels within the respective thermally active regions. These fluid flow channels have a reduced resistance to fluid flow and facilitate mixing of the fluid exiting finned regions into the fluid flow channels. Moreover, for those fluid flow channels where the fins are completely removed, the fluid is in direct contact with the bottom surface of the device, thereby improving localized heat transfer into the fluid. In addition, in some of the embodiments disclosed herein, the pitch of the fins is varied in the respective devices. Accordingly, altering the size and shape of the fins in certain predetermined regions as well as the fin densities facilitates designing and fabricating the respective devices with specific heat transfer capabilities.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A heat removal device for enhancing external hose routing, the heat removal device comprising:
a body comprising:
a first wall, wherein the first wall defines a first fluid aperture and a second fluid aperture;
a second wall opposing the first wall, wherein:
the first wall at least partially defines a first lateral axis and a second lateral axis perpendicular to the first lateral axis; and
a first fluid riser in flow communication with the first fluid aperture, wherein the first fluid riser is positionally fixed, the first fluid riser is oriented to channel fluid into the body in a first direction at a first angle with respect to the first lateral axis;
a first fluid conduit in flow communication with the first fluid riser;
a second fluid riser in flow communication with the second fluid aperture, wherein the second fluid riser is positionally fixed; and
a second fluid conduit in flow communication with the second fluid riser, the second fluid riser is oriented to channel the fluid from the body in a second direction at a second angle with respect to the first lateral axis.

2. The heat removal device of claim 1, wherein:
an absolute value of the second angle equals an absolute value of the first angle; and
the first fluid riser and the second fluid riser are positioned in opposition with respect to the first lateral axis and coincident with the second lateral axis.

3. The heat removal device of claim 2, wherein:
the first fluid riser and the second fluid riser are oriented symmetrically with respect to one of the first lateral axis and the second lateral axis.

4. The heat removal device of claim 1, wherein:
the first fluid riser and the second fluid riser are oriented to facilitate access to a heat generating device positioned under the body.

5. The heat removal device of claim 1, further comprising:
mechanical mounting hardware for coupling the body to a heat generating device, wherein the first fluid riser, the first fluid conduit, the second fluid riser, and the second fluid conduit are oriented to not interfere with access to the mechanical mounting hardware.

6. The heat removal device of claim 1, wherein the heat removal device has:
a length defined along the first lateral axis, wherein the length has a length value;
a width defined along the second lateral axis, wherein the width has a width value; and
a height defined along an axis orthogonal to the first lateral axis and the second lateral axis, wherein the height has a height value that is less than the length value and the width value.

7. The heat removal device of claim 1, wherein:
the first fluid riser and the second fluid riser are oriented to receive the respective first fluid conduit and the second fluid conduit from a same side of the heat removal device.

8. The heat removal device of claim 1, wherein:
the first fluid riser and the second fluid riser are oriented to receive the respective first fluid conduit and the second fluid conduit from opposing sides of the heat removal device.

9. A heat removal device for enhancing internal flow distribution, the heat removal device comprising:
a body comprising:
a first wall, wherein the first wall defines:
a first lateral axis and a second lateral axis perpendicular to the first lateral axis, the first lateral axis and the second lateral axis intersect to define a geometric center of the body; and
a first fluid aperture and a second fluid aperture disposed parallel to the second lateral axis and separated by the first lateral axis;
a second wall opposing the first wall;
a third wall orthogonal to the first wall and the second wall, the third wall coupled to the first wall and the second wall, wherein the first wall, the second wall, and the third wall define an outer periphery;
a thermally active region defined by the first wall, the second wall, and the third wall, wherein the thermally active region defines an inner periphery, the inner periphery and the outer periphery are fluidly sealed; and
a plurality of fins resident in the thermally active region extending from the second wall toward the first wall along an axis orthogonal to the first lateral axis and the second lateral axis, wherein:
the plurality of fins define one or more heights, one or more orientations, and one or more pitches;
the plurality of fins are thermally conductive; and
the plurality of fins are configured to channel a fluid from the first fluid aperture to the second aperture through a predetermined flow distribution defined by the one or more heights, the one or more orientations, and the one or more pitches.

10. The heat removal device of claim 9, wherein:
the inner periphery is concentric with the outer periphery; and
the plurality of fins extends along the second lateral axis, wherein the plurality of fins define one or more fluid distribution regions comprising:
a fluid entrance flow distribution region that extends parallel to the first lateral axis;
a fluid exit flow distribution region that extends parallel to the first lateral axis; and
a plurality of heat transfer flow distribution regions that extend parallel to the second lateral axis, wherein the fluid entrance flow distribution region, the fluid exit flow distribution region, and the plurality of heat transfer flow distribution regions are coupled in flow communication.

11. The heat removal device of claim 10, wherein:
the fluid entrance flow distribution region is coupled in flow communication with the first fluid aperture; and
the fluid exit flow distribution region is coupled in flow communication with the second fluid aperture, wherein the fluid entrance flow distribution region and the fluid exit flow distribution region are configured to induce a predetermined fluid flow distribution within the body.

12. The heat removal device of claim 10, wherein:
the fluid entrance flow distribution region and the fluid exit flow distribution region are formed through one of more of:
reducing a height of a respective first portion of the plurality of fins; and
removing a respective second portion of the plurality of fins.

13. The heat removal device of claim 10, wherein:
the fluid entrance flow distribution region defines a first flow area and the fluid exit flow distribution region defines a second flow area that is different from the first flow area to induce a predetermined fluid distribution about the plurality of fins.

14. The heat removal device of claim 10, further comprising:
one or more fluid channels defined proximate an inner periphery of the body, wherein at least a portion of the one or more fluid channels are oriented one or more of:
parallel to the first lateral axis; and
parallel to the second lateral axis.

15. The heat removal device of claim 14, further comprising:
a first fluid channel parallel to the first lateral axis configured to receive at least a portion of the fluid entering the thermally active region; and
a second fluid channel parallel to the first lateral axis configured to receive at least a portion of the fluid exiting the thermally active region.

16. The heat removal device of claim 15, wherein:
the first fluid channel defines a first flow area and the second fluid channel defines a second flow area that is different from the first flow area to induce a predetermined fluid distribution about the plurality of fins.

17. The heat removal device of claim 14, further comprising:
a third fluid channel parallel to the second lateral axis configured to receive at least a portion of the fluid exiting the first fluid channel; and
a fourth fluid channel parallel to the second lateral axis configured to receive at least a portion of the fluid exiting the first fluid channel.

18. The heat removal device of claim 14, wherein the plurality of fins comprises:
a first plurality of fins with a first fin density, wherein the first plurality of fins is positioned between the first fluid channel, the second fluid channel, the third fluid channel, and the fourth fluid channel; and
a second plurality of fins with a second fin density that is less than the first fin density, wherein the second plurality of fins is positioned in one of the third fluid channel and the fourth fluid channel.

19. A method of manufacturing a cold plate, the method comprising:
arranging a plurality of fluid risers and fluid conduits on a top wall of the cold plate such that access to mechanical mounting hardware positioned proximate the top wall of the cold plate is not inhibited, comprising:
forming a first fluid aperture and a second fluid aperture in the top wall of the cold plate;
coupling the top wall of the cold plate to a bottom wall of the cold plate in opposition to each other, thereby at least partially defining a thermally active region;
fixedly coupling a first fluid riser to the first fluid aperture and fixedly coupling a second fluid riser to the second fluid aperture; and
coupling a first fluid conduit to the first fluid riser and coupling a second fluid conduit to the second fluid riser; and
coupling a heat generating device to the bottom wall of the cold plate though the mechanical mounting hardware.

20. The method of claim 19, further comprising:
forming a predetermined flow path in the thermally active region, comprising:
positioning a plurality of fins on the bottom wall of the cold plate;
removing at least a portion of the plurality of fins to form a plurality of flow distribution regions, comprising one or more of:
reducing a height of a respective first portion of the plurality of fins; and
removing a respective second portion of the plurality of fins; and
adjusting a fin pitch of remaining fins.
